(19) United States
(12) Patent Application Publication
(10) Pub. No.: US 2025/0305181 A1
(43) Pub. Date: Oct. 2, 2025

(54) INGOT PULLER APPARATUS INCLUDING COOLING JACKET WITH VARYING SURFACE EMISSIVITY FOR CONTROLLED INGOT COOLING PROFILES

(71) Applicant: GlobalWafers Co., Ltd., Hsinchu (TW)

(72) Inventors: Zheng LU, O'Fallon, MO (US); Sumeet S. BHAGAVAT, St. Charles, MO (US); William L. LUTER, St. Charles, MO (US)

(21) Appl. No.: 18/622,211

(22) Filed: Mar. 29, 2024

(51) Int. Cl. C30B 15/20; C30B 15/10

(52) U.S. Cl. CPC C30B 15/206; C30B 15/10

(57) ABSTRACT

An ingot puller apparatus for producing a single crystal ingot includes a housing defining a growth chamber and a growth chamber outlet, a crucible positioned in the growth chamber for containing a melt of semiconductor material, a cooling jacket positioned in the growth chamber between the crucible and the growth chamber outlet and including an inner surface defining a cooling passage having an inlet proximate the crucible and an outlet proximate the growth chamber outlet, and a puller positioned to pull the single crystal ingot from the melt and through the cooling passage. The inner surface of the cooling jacket includes a first surface region having a first emissivity coefficient and a second surface region having a second emissivity coefficient larger than the first emissivity coefficient to control a cooling profile of the single crystal ingot.

### FIELD

The field relates generally to manufacture of single crystal ingots of semiconductor material and, more specifically, to single crystal ingot pulling apparatus including a cooling jacket, and to related methods for controlled cooling of single crystal ingots.

### BACKGROUND

Single crystal semiconductor material, such as a single crystal silicon wafer, is the starting material for fabricating many electronic components such as semiconductor devices. Single crystal silicon material is commonly prepared using the Czochralski (“CZ”) method. The Czochralski method involves melting polycrystalline silicon (“polysilicon”) in a crucible to form a silicon melt, and then pulling a single crystal silicon ingot from the melt. Single crystal silicon wafers can then be sliced from the ingot using a wire saw or another suitable cutting technique and used as a base substrate for fabricating electronic devices.

The continuously shrinking size of modern electronic devices imposes challenging restrictions on the quality of the single crystal silicon substrate, which is determined, at least in part, by the size and the distribution of grown-in defects in the ingot crystal structure. Defects formed in single crystal silicon ingots grown by the Czochralski method include voids, or agglomerates of intrinsic point defects of silicon (i.e., vacancies and self-interstitials), and oxygen precipitates which may lead to gate-oxide-integrity (GOI) failures. Such failures can be particularly troubling for Perfect Silicon (PS) wafer products that are used, for example, for new generation memory devices.

Known systems and methods attempt to control the number and/or size of defects in the single crystal ingot by adjusting components of a “hot zone” of the growth chamber including, for example, heaters, insulation, heat shield(s), radiation shield(s), and/or cooling components. The hot zone influences the overall thermal profile within the growth chamber, and the thermal profile influences thermal gradients in the core of the ingot as well as a profile of an interface between the melt and the growing crystal (the solid-melt interface). Thermal gradients and the solid-melt interface profile may control, at least in part, incorporation and/or nucleation of in-grown defects, such as vacancies and oxygen precipitates, in the ingot during growth.

Known methods and ingot puller apparatus have been less than satisfactory for addressing and/or reducing the number and/or size of defects (e.g., voids and oxygen precipitates) in single crystal silicon ingots. Accordingly, a need exists for ingot puller apparatus and methods for producing single crystal silicon ingots with fewer defects and defects having a smaller average size.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect is an ingot puller apparatus for producing a single crystal ingot. The ingot puller apparatus includes a housing defining a growth chamber and a growth chamber outlet, a crucible positioned in the growth chamber for containing a melt of semiconductor material, a cooling jacket positioned in the growth chamber between the crucible and the growth chamber outlet and including an inner surface defining a cooling passage having an inlet proximate the crucible and an outlet proximate the growth chamber outlet, and a puller positioned to pull the single crystal ingot from the melt and through the cooling passage. The inner surface of the cooling jacket includes a first surface region having a first emissivity coefficient and a second surface region having a second emissivity coefficient larger than the first emissivity coefficient to control a cooling profile of the single crystal ingot.

Another aspect is a method of producing a single crystal ingot. The method includes preparing a melt of semiconductor material in a crucible positioned in a growth chamber of an ingot puller apparatus, contacting the melt with a seed crystal, pulling the seed crystal from the melt to grow the single crystal ingot, and cooling the single crystal ingot during growth using a cooling jacket positioned in the growth chamber. The single crystal ingot is pulled through a cooling passage defined by an inner surface of the cooling jacket. The method also includes controlling a cooling profile of the single crystal ingot using different emissivity coefficients of the inner surface.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a partially schematic view of a portion of an ingot puller apparatus for producing a single crystal ingot that includes a cooling jacket for cooling the ingot;

FIG. 2 is a schematic section of the cooling jacket of the ingot puller apparatus of FIG. 1;

FIG. 3 is an example of the cooling jacket shown in FIG. 2 in which an inner surface is coated with an emissive coating material;

FIG. 4 is another example of the cooling jacket shown in FIG. 2 in which the inner surface is coated with two bands of emissive coating material having different emissivity coefficients for controlling a cooling profile of the ingot;

FIG. 5 is another example of the cooling jacket shown in FIG. 2 in which the inner surface is coated with three bands of emissive coating material having different emissivity coefficients for controlling a cooling profile of the ingot;

FIG. 6 is another example of the cooling jacket shown in FIG. 2 in which the inner surface is coated with four bands of emissive coating material having different emissivity coefficients for controlling a cooling profile of the ingot;

FIG. 7 is another example of the cooling jacket shown in FIG. 2 in which the inner surface is coated with an emissive coating material having an emissivity coefficient that gradually changes according to an emissivity gradient for controlling a cooling profile of the ingot;

FIGS. 8-10 depict examples of the cooling jacket shown in FIG. 2 in which the inner surface is coated with vertical bands of emissive coating material for controlling a cooling profile of the ingot;

FIGS. 11 and 12 are schematic cross-sections of a portion of another ingot puller apparatus including a moveable cooling jacket for controlling a cooling profile of the ingot, respectively showing the cooling jacket in a lowered position and a raised position;

FIG. 13 is an enlarged view of a bellows included in the ingot puller apparatus of FIGS. 11 and 12 for moving the cooling jacket, with various components of the ingot puller apparatus omitted for ease of illustration and description;

FIG. 14 is a plot of simulated temperature gradients between a surface of an ingot at a solid-melt interface and the cooling jacket, measured at different stages of the ingot growth process, for three different cooling jacket configurations;

FIG. 15 is a plot of simulated temperature gradients between a surface of an ingot and the cooling jacket, measured at different body length positions of the ingot, for the three different cooling jacket configurations used in FIG. 14;

FIG. 16 is a plot of simulated temperature gradients between a surface of an ingot at a solid-melt interface and the cooling jacket, measured at different stages of the ingot growth process, for three different cooling jacket positions relative to a melt surface;

FIG. 17 is a plot of simulated temperature gradients between a surface of an ingot and the cooling jacket, measured at different body length positions of the ingot, for the three different cooling jacket positions used in FIG. 16; and

FIG. 18 is a plot of simulated temperature gradients between a surface of an ingot at a solid-melt interface and the cooling jacket, measured at different stages of the ingot growth process, for the three different cooling jacket positions in FIG. 16 and a process in which the cooling jacket position changes after growth of a predetermined length of the ingot.

Corresponding reference characters indicate corresponding parts throughout the several views of the drawings.

### DETAILED DESCRIPTION

The systems and methods of this disclosure include a cooling jacket positioned in a growth chamber of an ingot puller apparatus used to grow a single crystal ingot. The cooling jacket defines a cooling passage through which the single crystal is pulled and cools the ingot during growth according to a desired cooling profile. An example cooling profile includes rapidly cooling or quenching the ingot to solidify the ingot near the solid-melt interface and further cooling the ingot as the ingot is pulled through the cooling passage. The rapid cooling of the ingot near the solid-melt interface may reduce a number of defects (e.g., intrinsic point defects) that are available in the ingot to agglomerate to form large grown-in defects. After rapidly solidifying the ingot, the further cooling of the ingot is provided to allow any defects incorporated in the ingot near the lateral edge to diffuse radially inward and distribute evenly throughout the core of the ingot without agglomerating in localized, high concentration regions, and eventually “freeze” the defects (or inhibit defect agglomeration) by cooling the ingot below a nucleation temperature. The example cooling jackets of this disclosure facilitate efficient and well-controlled cooling of single crystal ingot to achieve and optimize the cooling profile of the ingot, which may facilitate maximizing the reduction or elimination of defects using the cooling jacket and improving the quality of the ingot.

In some examples, the cooling jacket includes surface regions having different emissivity and heat absorptivity such that desired temperature gradients between the cooling jacket and different body length portions of the ingot can be achieved during and after ingot growth to achieve desired cooling profiles. The emissivity and heat absorptivity of each surface region may be controlled to achieve the desired cooling efficiency at different locations within the cooling passage without generating excessive transient temperatures and gradients that can negatively impact crystal growth and crystal quality at other locations (e.g., near the solid-melt interface). In some such examples, the surface emissivity of the cooling jacket may be reduced proximate an inlet of the cooling passage, creating a relatively lower cooling zone at the inlet, which allows the cooling jacket to be placed closer to a surface of the melt without creating transient temperatures and gradients near the solid-melt interface that could cause unstable crystal growth and poor crystal quality. In this way, the cooling jacket can facilitate optimizing both high temperature gradients and cooling rates in desired locations without creating excessive transient temperatures and gradients at the initial stages of ingot growth and/or at locations of the ingot near the solid-melt interface.

The cooling jacket may be additionally and/or alternatively moveable within the growth chamber to control a view factor between the ingot and the cooling jacket, that is, a fraction of thermal power reaching the ingot from the cooling jacket. In some such examples, the cooling jacket is moveable vertically in the growth chamber during one or more stages of the ingot growth process to adjust the view factor and achieve a desired heat transfer efficiency at different locations of the ingot. For example, the cooling jacket may be raised to a relatively higher position when a lower temperature gradient and cooling rate at the solid-melt interface are desired, such as at the beginning of the ingot growth process, and the cooling jacket may be lowered to a relatively lower position when a higher temperature gradient and cooling rate at the solid-melt interface are desired, such as after a portion of a main body of the ingot has been grown. The position of the cooling jacket may be adjusted according to a predetermined profile, generated based on thermal simulation as well as empirical temperature and gradient measurements, and/or dynamically based on measured parameters in the growth chamber during ingot growth. In this way, movement of the cooling jacket can facilitate optimizing temperature gradients and cooling efficiency at selected locations of the ingot and/or at selected ingot growth stages without generating excessive transient temperatures and gradients that have negative impacts to ingot growth and crystal quality at other locations and/or at other stages of ingot growth.

Example systems and methods enable cooling profiles of single crystal ingots that include multiple, localized cooling rates and temperature gradients within the cooling passage as the ingot is pulled therethrough. The cooling rates and temperature gradients may be closely controlled depending on the various transport and nucleation mechanisms of defects at various stages of crystal growth, such that the size and/or concentration of defects incorporated into the crystal during growth are reduced or eliminated. Notably, the systems and methods described may facilitate reducing the size of voids and oxygen precipitates in the grown-in edge band of substantially defect-free or “perfect-silicon” crystals, which reduces the propensity for GOI failures and yield loss. Example systems and methods also simplify the design of cooling jackets that are able to provide such control of the cooling profile of the ingot, which reduces costs and provides repeatable and consistent cooling capabilities.

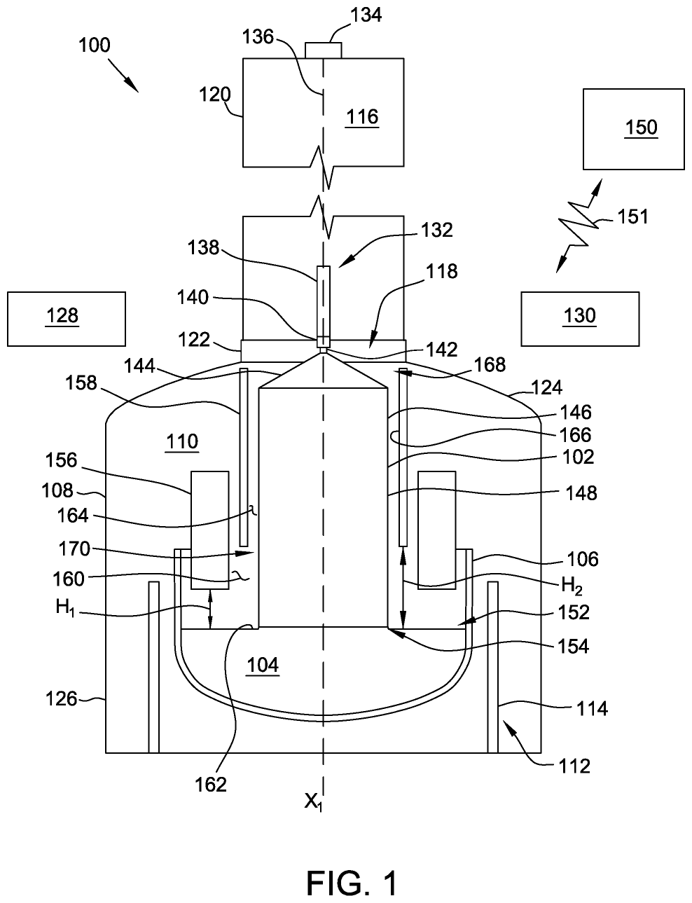

Referring now to the drawings, an example ingot puller apparatus or ingot puller is indicated generally at 100 in FIG. 1. The ingot puller 100 is used to produce single crystal ingots 102 of semiconductor material such as, for example, single crystal silicon ingots 102. The ingot 102 is grown by the so-called Czochralski (CZ) method in which the ingot 102 is withdrawn or pulled from a melt 104 (e.g., a silicon melt) held within a crucible 106 of the ingot puller 100. The crucible 106 may be made of, for example, quartz or any other suitable material that enables the crucible 106 to function as described.

The ingot puller 100 may be operable to grow the ingot 102 by a batch CZ process or a continuous CZ process. In the batch CZ process, polycrystalline semiconductor material (e.g., polycrystalline silicon) is charged to the crucible 106 in an amount sufficient to grow one ingot 102, such that the crucible 106 is essentially depleted of the melt 104 after growth of the one ingot 102. In the continuous CZ process, polycrystalline semiconductor material (e.g., polycrystalline silicon) is continually or periodically added to the crucible 106 to replenish the melt 104 during the growth process such that multiple ingots 102 can be grown from the melt 104. Unless stated otherwise, embodiments of the subject matter described herein are not limited to a particular crystal growth process. The ingot puller 100 is not limited to CZ method applications.

The ingot puller 100 includes a housing 108 that defines a growth chamber 110. The crucible 106 is disposed within the growth chamber 110. The crucible 106 contains the melt 104 from which the ingot 102 is pulled. The crucible 106 may be supported by a graphite support or susceptor (not shown) operably connected to a shaft (not shown). The ingot puller 100 may be configured to rotate the crucible 106 and/or move the crucible 106 vertically within the growth chamber 110 during the ingot growth process. For example, the ingot puller 100 may include a crucible drive unit (not shown), such as a rotary motor, that rotates the crucible 106 and the susceptor and shaft supporting the crucible 106. The ingot puller 100 may additionally or alternatively include a crucible lift unit (not shown), such as a linear actuator, that raises and lowers the crucible 106. The crucible 106 may be rotated about a pull axis X₁ of the ingot puller 100, or about a rotational axis parallel to the pull axis X₁, and/or moved vertically along or parallel to the pull axis X₁. Rotational and vertical movement of the crucible 106 may be controlled throughout the ingot growth process by a controller 150 of the ingot puller 100.

The ingot puller 100 also includes an ingot removal chamber 116 positioned above the crucible 106 and connected to an outlet 118 of the growth chamber 110. The ingot removal chamber 116 is defined by a tubular vessel 120 connected to an outlet flange 122 of the housing 108 that defines the outlet 118. The outlet flange 122 is positioned on an upper dome 124 of the housing 108. The upper dome 124 extends from a cylindrical side portion 126 of the housing 108. The tubular vessel 120 extends from the upper dome 124 such that the ingot removal chamber 116 extends vertically above the outlet 118 of the growth chamber 110. The outlet 118 and the ingot removal chamber 116 each have a generally annular or circular cross-section and are sized and shaped to accommodate the ingot being pulled therethrough from the melt 104.

The housing 108 and tubular vessel 120 are made of stainless steel or other suitable materials. In some examples, one or more of the upper dome 124, the side portion 126, and the tubular vessel 120 may include fluid-cooled (e.g., water-cooled) stainless steel walls. One or more of the upper dome 124, the side portion 126, and the tubular vessel 120 may include view ports or sight glasses (not shown) to monitor parameters of the growth chamber. The ingot puller 100 may include one or more temperature sensors 128 (e.g., pyrometers) and one or more infrared (IR) cameras 130 located outside the growth chamber 110 and positioned to view selected regions within the growth chamber 110 for monitoring parameters (e.g., temperatures, gradients, melt level, etc.) within the growth chamber 110 during the ingot growth process. The pyrometer 128 and IR camera 130 may monitor parameters through view ports in the upper dome 124 for example.

To prepare the melt 104, polycrystalline semiconductor material (e.g., polycrystalline silicon) is added to the crucible 106. The polycrystalline semiconductor material is heated to above the melting temperature of the material (e.g., about 1414° C. for polycrystalline silicon) to cause the polycrystalline semiconductor material to liquefy into the melt 104. In some examples, the melt 104 is heated to a temperature of at least about 1425° C., at least about 1450° C., or at least about 1500° C.

A heat source 112 is operated to melt-down the polycrystalline silicon and form the melt 104. For example, the heat source 112 includes one or more “side” heaters 114 mounted within the growth chamber 110 to the side of (i.e., radially outward from) the crucible 106 that are operated to melt-down the polycrystalline semiconductor material to prepare the melt 104. The heat source 112 may additionally or alternatively include “bottom” heaters (not shown) mounted within the growth chamber 110 below the crucible 106. The side and bottom heaters 114 of the ingot puller 100 may be any type of heater that are capable of functioning as described. In some examples, the heaters 114 are resistance heaters. The heaters 114 may be controlled by the controller 150 such that the temperature of the melt 104 is controlled throughout the ingot growth process. The ingot puller 100 may also include side insulation (not shown) located radially outward of the side heaters 114 and/or bottom insulation (not shown) located below the bottom heaters to retain heat in the growth chamber 110.

The single crystal ingot 102 is pulled from the melt 104 using a pulling assembly 132. The pulling assembly 132 includes a lift or motor 134 (e.g., a winch) attached to a pull wire 136 that extends down from the lift 134. The lift 134 is located above the ingot removal chamber 116 and is operable to raise and lower the pull wire 136 through the ingot removal chamber 116 and growth chamber 110 along the pull axis X₁. The lift 134 may also be operable to rotate the pull wire 136 about the pull axis X₁. The ingot puller 100 may have a pull shaft rather than a wire 136, depending upon the type of puller. The pull wire 136 terminates at a seed chuck 138 that holds and/or is secured to a seed crystal 140.

The housing 108 may include one or more gas ports (not shown) for introducing a process gas (e.g., argon) into the growth chamber 110 and creating an inert atmosphere within the growth chamber 110. A surface 162 of the melt 104 and the inert atmosphere form a melt-gas interface 152. The melt-gas interface 152 is located radially outward from a solid-melt interface 154 along which the ingot 102 is grown.

The ingot puller 100 also includes the controller 150 communicatively connected to various components of the puller 100, including the heat source 112, the pulling assembly 132, the crucible drive unit, the crucible lift unit, the pyrometer 128, the IR camera 130, and other components including those described below such as a cooling jacket 158. Although a single controller 150 is shown and described, the controller 150 may include multiple controllers 150 that may be centralized or decentralized. The controller 150 controls various aspects and parameters of the ingot puller 100 during the ingot growth process 100. For example, the controller 150 controls electric current supplied to the heaters 114 to control the amount of thermal energy supplied by the heat source 112. The controller 150 also controls operation of the pulling assembly 132 and the movement of the crucible 106. For example, the controller 150 may control a pull rate of the pulling assembly 132, a rotation rate of the seed crystal 140, a rotation rate of the crucible 106, and/or a vertical position of the crucible 106 in the growth chamber 110.

The controller 150 may receive feedback and monitored process information from one or more sensors, such as the pyrometer 128 and the IR camera 130, for continuous, periodic, or intermittent monitoring of conditions within the growth chamber 110, such as the temperature of the melt 104, temperature at the solid-melt interface 154, surface level of the melt 104 (i.e., a vertical position of the melt surface 162), the temperature of the ingot 102, among other information. The sensors may be communicatively connected with controller 150 to provide feedback information about the ingot growth process to the controller 150.

The controller 150 may include a communication interface to communicatively couple the controller 150, via one or more connections 151, to one or more components of the ingot puller 100. For example, the one or more connections 151 may communicatively couple the controller 150 to the heat source 112, the pulling assembly 132, the crucible drive unit, the crucible lift unit, the pyrometer 128, the IR camera 130, the cooling jacket 158, and/or other components of the ingot puller 100. The communication interface may include, for example, a wired or wireless network adapter and/or a wireless data transceiver for use with a mobile telecommunications network. In this way, the one or more connections 151 may communicatively couple the controller 150 to the one or more components of the ingot puller 100 via a wired and/or wireless connection.

The ingot puller 100 also includes an annular heat shield 156 and a cooling jacket 158 that shroud the ingot 102 as it is pulled from the melt 104. The heat shield 156 and the cooling jacket 158 cooperate to drive solidification and crystallization of molten silicon in the melt 104 into the growing ingot 102. An example configuration of the heat shield 156 and the cooling jacket 158 will be described by way of example only, and may vary without departing from some aspects of this disclosure. The annular heat shield 156 and the cooling jacket 158 are each mounted within the growth chamber 110 above the melt 104. The heat shield 156 is mounted radially outward from the cooling jacket 158. The heat shield 156 is located a first distance, or height, H₁ above the melt surface 162 and the cooling jacket 158 is located a second distance, or height, H₂ above the melt surface 162. The first height H₁ and the second height H₂ may be the same or different. In some examples, the heat shield 156 is located closer to the melt surface 162 such that the first height H₁ is shorter than the second height H₂.

The heat shield 156 defines an insulating passage 160 sized and shaped to receive the ingot 102 as the ingot 102 is pulled up from the melt 104 along the pull axis X₁. The first height H₁ may be shorter than a height of the side wall of the crucible 106 such that the heat shield 156 extends down into the crucible 106 and is interposed between the growing ingot 102 and the crucible side wall, as shown in FIG. 1. The heat shield 156 insulates and/or reflects radiant heat towards and/or away from the ingot 102 as the ingot is pulled through the passage 160. In some examples, the heat shield 156 includes one or more annular reflectors made of suitable heat reflective materials including, for example and without limitation, graphite, silicon carbide coated graphite, and high purity molybdenum. In some such examples, the heat shield 156 includes two annular reflectors arranged co-axially with one another and an insulating layer between the two reflectors. The insulating layer may be constructed of a material having low thermal conductivity to insulate against heat transfer between the insulating passage 160 and areas of the growth chamber 110 radially outboard of the heat shield 156. The configuration of the heat shield 156 may be any suitable configuration to enable the heat shield 156 to function as described.

The cooling jacket 158 is positioned radially inward from the heat shield 156, and partially within the insulating passage 160. The cooling jacket 158 is concentrically arranged with the heat shield 156 along the pull axis X₁. The cooling jacket 158 is a fluid-cooled heat exchanger that includes an inner surface 166 defining a central cooling passage 164 for receiving the ingot 102 as the ingot 102 is pulled along the pull axis X₁ by the pulling assembly 132. Cooling fluid circulating in the cooling jacket 158 facilitates cooling the ingot 102 as the ingot 102 is pulled through the cooling passage 164. Dimensions of the cooling jacket 158 may vary based, for example, on the dimensions of the ingot puller 100, the size of the ingot 102, a desired length of the cooling passage 164, the temperature profile within the growth chamber 110, and/or the pull rate of the ingot 102.

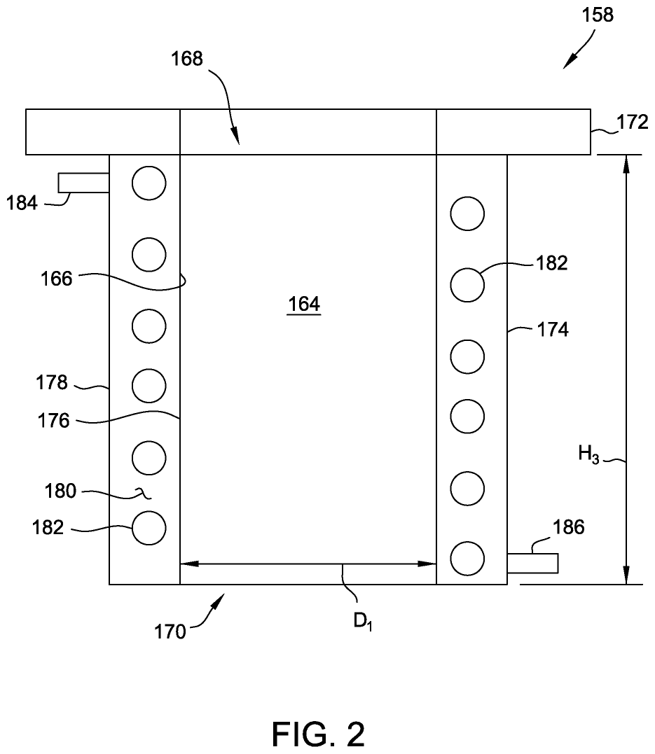

The cooling jacket 158 is mounted in the growth chamber 110 by a cooling jacket flange 172 (see FIG. 2) connected between the outlet flange 122 and the tubular vessel 120. An outlet 168 of the cooling passage 164 is defined adjacent the outlet 118 of the growth chamber 110. A main housing 174 (see FIG. 2) of the cooling jacket 158 extends down from the cooling jacket flange 172 into the growth chamber 110 and into the insulating passage 160 defined by the heat shield 156. The main housing 174 includes the inner surface 166 that defines the cooling passage 164. An inlet 170 of the cooling passage 164 is defined proximate the surface 162 of the melt 104. A height of the cooling passage inlet 170 above the melt surface 162 is determined by the height H₂ of the cooling jacket 158 above the melt surface 162. The height H₂ varies and may depend on various considerations including, for example and without limitation, allowing a flow of purge gas between the melt 104 and the cooling jacket 158 without creating surface disruptions in the melt surface 162, the pull rate of the ingot 102, enabling rapid cooling of the ingot 102 as it is pulled from the melt 104, providing a zone of cooling between the solid-melt interface 154 and the cooling passage 164 to grow a portion of the ingot 102 over a temperature range between a solidification temperature and a nucleation temperature of defects incorporated into the ingot 102, minimizing particle deposition on the cooling jacket 158, among other considerations such as those described elsewhere.

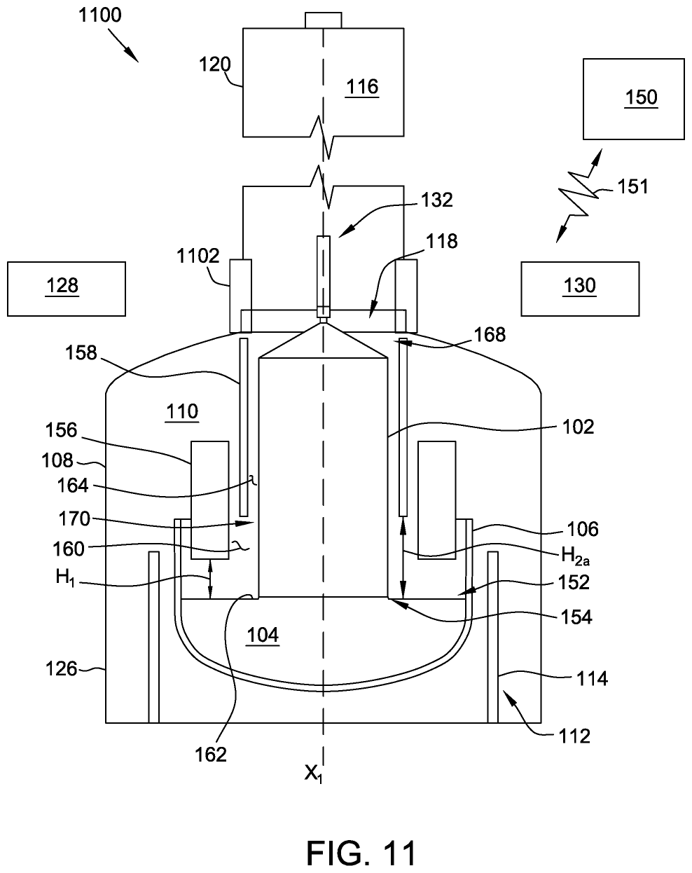

In some examples, the cooling jacket 158 is moveable in the growth chamber 110 such that the height H₂ is adjustable before, during, and/or after the ingot growth process. Examples that include a moveable cooling jacket 158 are described in more detail below with reference to FIGS. 11-13.

Referring to FIG. 2, the housing 174 of the cooling jacket 158 is cylindrical in shape. The cooling passage 164 has a circular cross-section and an inner diameter Di of the cylindrical housing 174 defines a diameter of the cooling passage 164. The diameter Di is sized to allow the ingot 102 to be pulled through the cooling passage 164 without contacting the cooling jacket 158. The diameter Di may vary depending on the size (e.g., outer diameter) of the ingot 102. The housing 174 also extends a vertical distance, or height, H₃ between the inlet 170 and the outlet 168 of the cooling passage 164. The height H₃ defines the length of the cooling passage 164. The height H₃ may vary depending on the size (e.g., axial length) of the ingot 102.

The housing 174 of the cooling jacket 158 includes an inner panel 176 and an outer panel 178 spaced radially outward from the inner panel and arranged relative to each other to define an interior cooling chamber 180. The inner panel 176 defines the inner surface 166. A cooling tube 182 is disposed in the interior chamber 180. The cooling tube 182 is shown with features simplified for ease of illustration and description. The cooling tube 182 a helical coil construction, with turns of the cooling tube 182 circumscribing and in close contact with the inner panel 176 of the housing 174. The cooling tube 182 may be sized relative to the jacket housing 174 such that the turns of the cooling tube 182 are also in close contact relationship with the outer panel 178 of the housing. In addition or in the alternative to the cooling tube 182, the interior cooling chamber 180 may be generally hollow for circulating a cooling fluid (e.g., cold water) therethrough.

The cooling tube 182 is fluidly connected to a suitable cooling fluid source, such as a cold water source, via an inlet fitting 184 that receives cooling fluid into the interior chamber 180 of the cooling jacket 158. The interior chamber 180 of the cooling jacket housing 174 is fluidly connected to an outlet fitting 186 to exhaust cooling fluid from the cooling jacket 158.

The turns of the cooling tube 182 wind downward within the interior chamber 180 of the cooling jacket housing 174 to direct cooling fluid down through the cooling tube 182. In some embodiments, the lowermost turn of the cooling tube 182 may be open so that cooling fluid is exhausted from the cooling tube 182 into the interior chamber 180 of the cooling jacket housing 174, and directed toward the outlet fitting 186. The cooling jacket 158 may also include one or more baffles (not shown) within the interior chamber 180 to direct cooling fluid exhausted from the cooling tube 182 to desired portions of the cooling jacket housing 174, such as towards the outlet fitting 186.

In the example embodiment, the cooling jacket 158, including the housing 174 and the cooling tube 182, are constructed of steel (e.g., stainless steel). The cooling jacket 158 may be constructed from materials other than steel in other example. The cooling tube 182 may have a construction other than a helical coil construction, such as by being formed as an annular ring (not shown) or other plenum structure (not shown) that circumscribes all or part of the inner panel 176 of the cooling jacket housing 174.

Referring to FIGS. 1 and 2, in an example operation of the ingot puller 100, when the melt 104 is prepared in the crucible 106, the lift 134 lowers the seed chuck 138 and seed crystal 140 along the pull axis X₁ until the seed crystal 140 contacts the surface 162 of the melt 104. The seed crystal 140 begins to melt and the lift 134 slowly raises the seed crystal 140 along the pull axis X₁ from the melt 104. Atoms from the melt 104 align themselves with and attach to the seed crystal 140 to grow the ingot 102 which solidifies and is extracted from the melt 104. The seed crystal 140 and growing ingot 102 may also be rotated about the pull axis X₁ while being raised. Additionally or alternatively, the crucible 106 may be rotated as the ingot 102 is grown from the melt. In some examples, the seed crystal 140 and the crucible 106 are rotated in opposite directions.

As shown in FIG. 1, the ingot 102 grown in accordance with the CZ method includes a neck 142, an outwardly flaring portion 144 (referred to as a “crown” or “cone”), and a cylindrical main body 146. The neck 142 is attached to the seed crystal 140 that is contacted with the melt and withdrawn to form the ingot 102. The main body 146 is suspended from the neck 142. The neck 142 terminates once the cone portion 144 of the ingot 102 begins to form. The cone 144 extends between the neck 142 and the main body 146 in outwardly-flaring fashion such that the outer diameter defined by an outer surface 148 of the ingot 102 gradually increases along the cone 144. The outer diameter is greatest (and substantially constant) along the main body 146 of the ingot 102. The diameter of the main body 146 may vary depending on the intended application of the single crystal material and, in some embodiments, the diameter may be about 150 mm, about 200 mm, about 300 mm, greater than about 300 mm, about 450 mm, or greater than about 450 mm. A central axis of the ingot 102, which passes through the neck 142, cone 144, and main body 146, is substantially coaxial with the pull axis X₁. The single crystal ingot 102 may generally have any resistivity. The single crystal ingot 102 may be doped or undoped.

During growth, the ingot 102 is pulled up through the insulating passage 160 defined by the heat shield 156 and the cooling passage 164 defined by the cooling jacket 158. The heat shield 156 insulates and/or reflects heat toward and/or away from the ingot 102 in the insulating passage 160. The cooling jacket 158 receives cooling fluid (e.g., cold water) into the interior chamber 180 from the cooling fluid source via inlet fitting 184, and the cooling fluid flows downward through the cooling tube 182 towards the outlet fitting 186 where it exits the chamber 180. With the cooling tube 182 in close contact relationship with the inner panel 176 of the housing 174, conductive heat transfer occurs between the inner panel 176 and the cooling fluid in the cooling tube 182 to cool the inner panel 176 and the inner surface 166. Thermal energy is transferred between the cold inner panel 176 and the growing ingot 102, which facilitates solidifying the crystal.

Suitably, the ingot 102 is subjected to multiple cooling rates and thermal gradients as it is pulled from the melt 104 and through the cooling passage 164. The configuration and position of the cooling jacket 158 in the growth chamber 110 relative to the melt 104 may result in multiple different “cooling zones” arranged vertically along the pull axis X₁ of the ingot puller 100, each cooling zone being defined by the particular cooling conditions experienced by the ingot 102 within that zone. For example, a first cooling zone may be defined proximate the solid-melt interface 154, a second cooling zone may be defined between the first cooling zone and the inlet 170 of the cooling passage 164, and a third cooling zone may be defined within the cooling passage 164. These cooling zones are provided by way of example only. There may be more cooling zones, for example, any one of the described cooling zones may include discrete sub-cooling zones each with its own cooling conditions.

In one example operation of the ingot puller 100, the first cooling zone proximate the solid-melt interface 154 has an enhanced or relatively high cooling rate, and may be used to “quench” or rapidly cool the ingot 102 (or an axial segment thereof) to a temperature below a solidification temperature of the ingot 102 (e.g., about 1100° C. for silicon ingots). The cooling rate of the first cooling zone may be, for example and without limitation, in the range of about 2° C./minute to about 4° C./minute. The second cooling zone between the first cooling zone and the inlet 170 of the cooling passage 164 has a relatively slower cooling rate, since the temperature gradients within this region are smaller after the rapid solidification of the ingot 102, and the ingot 102 in this zone is within the insulating passage 160 and not within the cooling passage 164. The ingot 102 (or an axial segment thereof) may be cooled in the second cooling region from a temperature below the solidification temperature of the ingot 102 (e.g., 1100° C.) down to a nucleation temperature (e.g., 900° C.) of defects incorporated into the ingot 102. The cooling rate of the second cooling zone may be, for example and without limitation, in the range of about 0.5° C./minute to about 1.5° C./minute. The third cooling zone within the cooling passage 164 may have an enhanced or relatively higher cooling rate than the second cooling zone. The ingot 102 (or an axial segment thereof) may be cooled in the third cooling zone from a temperature at or near a defect nucleation temperature (e.g., 900° C.) to a temperature below the defect nucleation temperature (e.g., 600° C.). The cooling rate of the third cooling zone may be, for example and without limitation, in the range of about 1.5° C./minute to about 2.5° C./minute.

In each cooling zone, or at any vertical location along the pull axis X₁, heat transfer, ϕ_{q}, from the cooling jacket to the ingot at a cooling temperature T of the cooling jacket can be expressed as:

ϕ_{q}∝εσAFT⁴

Where ε is the surface emissivity coefficient of the cooling jacket, σ is the Stefan-Boltzmann constant, A is the surface area of the cooling jacket 158, and F is the view factor (the fraction of cooling power reaching the ingot 102). The heat transfer efficiency between the ingot 102 and cooling jacket 158 can be increased by increasing the emissivity coefficient ε of the cooling jacket 158, increasing the surface area A and view factor F, and/or reducing the cooling temperature T of the cooling jacket 158 (e.g., by reducing a temperature of cooling fluid circulating in the cooling tube 182). The surface area A and cooling temperature T of the cooling jacket 158 may be limited by size and other operational constraints of the ingot puller apparatus 100. For example, the size of the cooling jacket 158, which determines the available surface area A, may be limited by size constraints of the growth chamber 110. The temperature T of the cooling jacket 158 may be limited by the temperature of the cold water that can practically be delivered to the cooling jacket 158 in an efficient and cost-effective manner.

Examples of the cooling jacket 158 will now be described that facilitate controlling cooling profiles of the ingot 102 within the multiple cooling zones, or at different vertical locations along the pull axis X₁, by controlling the emissivity coefficient & of the inner surface 166 and/or the view factor F between the cooling jacket 158 and the ingot 102. According to Kirchhoff's law of thermal radiation, the surface emissivity of the cooling jacket 158 is directly related to the heat absorptivity of the cooling jacket 158. Alternatively stated, increasing the emissivity coefficient ¿ of the cooling jacket 158 increases its capacity to absorb and exchange heat and cool the ingot 102. The view factor F, which is defined by the fraction thermal power reaching the ingot 102 from the cooling jacket 158, can be increased by increasing the retention time of the ingot 102 in the cooling passage 164 (e.g., by reducing the length of the second cooling zone). Since an increase in the view factor F means that a greater amount of cooling power reaches the ingot 102, this increases the cooling rate.

The surface emissivity of the cooling jacket 158 and view factor between the cooling jacket 158 and the ingot 102 parameters may be controlled to fine-tune the cooling rates and thermal gradients experienced by the ingot 102 and facilitate reducing or eliminating incorporation and nucleation of defects in the ingot 102. These parameters may also be controlled to balance the cooling rates and thermal gradients to achieve desired defect control while avoiding excessive transient temperatures and gradients, for example, in the first cooling zone proximate the solid-melt interface 154, which may negatively impact crystal growth and quality of the ingot 102. The emissivity coefficient & is controlled by varying the surface emissivity of the inner surface 166 at one or more surface regions. The view factor F is controlled by varying the position of the cooling jacket 158 in the growth chamber 110, and more particularly, the height H₂ between the inlet 170 of the cooling passage 164 and the surface 162 of the melt 104. These parameters may be controlled alone or in any combination. In this regard, the features of any example cooling jacket 158 described below can be implemented in combination with the features of any other example.

As described above, the cooling jacket 158 may be made of steel, such as stainless steel. This material has a relatively low emissivity coefficient. For example, the material of the cooling jacket 158 may have an emissivity coefficient of smaller than about 0.65, such as between about 0.1 to about 0.65. The surface emissivity of the cooling jacket 158 may be lower depending on the degree of surface polishing. Polished or reflective stainless steel surfaces may have an emissivity coefficient of between about 0.07 to about 0.1, for example. On the other hand, rough stainless steel surfaces may have an emissivity coefficient greater than 0.65. The examples cooling jackets 158 described below have a different surface emissivity (e.g., an emissivity coefficient of at least about 0.7) at one or more surface regions of the inner surface 166, relative to the base surface of the cooling jacket 158, to control the heat transfer efficiency between the cooling jacket 158 and the ingot 102 at vertical locations along the pull axis X₁.

In various examples, one or more surface regions of the inner surface 166 may have a higher surface emissivity, or emissivity coefficient, than another one or more surface regions of the inner surface 166. This may be achieved in a number of ways, some of which are described in more detail below. In some examples, one or more surface regions of the inner surface 166 may be coated with an emissive coating material having a larger emissivity coefficient (e.g., at least about 0.7) than the base material (e.g., steel) of the inner surface 166. The emissivity coefficient of the coated surface regions of the inner surface 166 may also vary, for example, by using different emissive coating materials, different emissive coating densities, and/or different coating patterns. In some examples, the inner surface 166 may have one or more uncoated surface regions, and the surface emissivity of the uncoated surface regions may also vary, for example, by using different degrees of roughness or polishing of the uncoated surface regions.

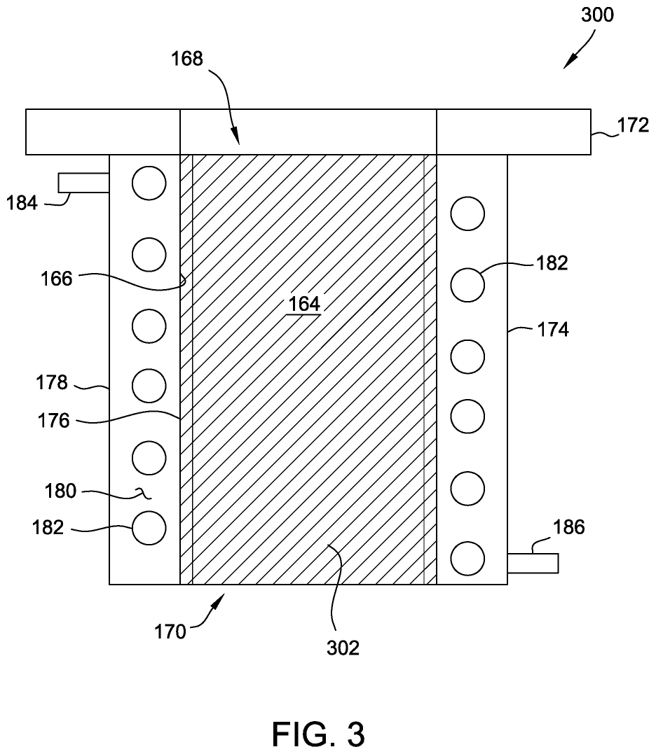

Referring to FIG. 3, in one example of the cooling jacket 158, indicated at 300, the inner surface 166 is coated with an emissive coating material 302. The emissive coating material 302 in this example covers the entirety, or a substantial majority, of the inner surface 166. The emissive coating material 302 also has a substantially constant emissivity coefficient, which is larger than the emissivity coefficient of the base material (e.g., steel) of the inner surface 166. For example, the emissive coating material may have an emissivity coefficient that is at least about 0.7, at least about 0.75, or at least about 0.8. The emissive coating material may have an emissivity coefficient in the range of between about 0.7 to about 0.99, such as between about 0.75 to about 0.99, or between about 0.8 to about 0.99.

The emissive coating material 302 may include any suitable emissive coating material that alters the surface emissivity properties of the inner surface 166 and enables the coated inner surface 166 to function as described. In some examples, the emissive coating material 302 is formed by treating the inner surface 166 to increase its surface emissivity, and the emissive coating material may also be referred to as an emissive surface treatment, an emissive conversion coating, and the like. In some such examples, the emissive coating material 302 is a black oxide material which has a relatively high emissivity, and a larger emissivity coefficient than the base material (e.g., steel) of the inner surface. That is, in some examples, the base material (e.g., steel) of the inner surface 166 is treated with black oxide. Black oxide is a chemical surface treatment which alters the properties of the steel base material, by forming a black iron oxide, to provide the inner surface 166 with a relatively higher emissivity value (e.g., at least about 0.7, at least about 0.75, or at least about 0.8).

Example black oxide surface treatments include contacting the ferrous metal (steel) of the inner surface 166 with a black oxide solution. This may be performed, for example, by dipping the steel material of the inner surface 166 into the black oxide solution and/or applying the black oxide solution to the steel material of the inner surface 166, such as spraying, brushing, or the like. In some examples, the inner surface 166 may be cleaned (e.g., with a chemical solution) prior to being brought into contact with the black oxide solution. Cleaning may be performed to remove rust, scale, grease, oil, or other contaminants from the steel material.

The black oxide coating is produced on the inner surface 166 by a chemical reaction between the iron on the base steel of the inner surface 166 and oxidizing agents present in the black oxide solution. The oxidizing agents may include, for example, water, atmospheric air, alkaline salts (e.g., sodium hydroxide, NaOH, sodium nitrate, NaNO₃, and/or sodium nitrite, NaNO₂), chromated oxidizing compounds (e.g., chromic acid, alkaline chromates such as Na₂Cr₂O₇ and/or K₂Cr₂O₇), and any combination thereof. The result of this chemical reaction is the formation of black iron oxide, also known as magnetite (Fe₃O₄), on the metal surface being coated. The black iron oxide may have an emissivity between about 0.7 to about 0.99, such as between 0.75 to about 0.99, or between about 0.8 to about 0.99.

The black oxide coating is suitably not treated with any finish treatment or sealant, such as, for example, oil (hydrophobic or hydrophilic), wax, lacquer, and/or acrylic, as this may contaminate the ingot 102. However, in some examples, the black oxide coating is treated with a finish or sealant, provided that such treatment is compatible with the ingot 102.

The emissive coating material 302 (e.g., black oxide) increases the emissivity coefficient of the inner surface 166 and, thereby, the heat transfer efficiency of the cooling jacket 158. The emissive coating material 302, applied uniformly across the inner surface 166 between the inlet 170 and outlet 168 of the cooling passage 164, may provide little to no control over transient temperatures and gradients at certain vertical locations and stages of the ingot growth process, which may lead to excessive transient temperatures and gradients that negatively impact crystal growth and/or ingot quality. For example, with the emissive coating material 302 on the inner surface 166 as shown in FIG. 3, transient temperatures and gradients at or near the solid-melt interface 154 at early stages of growth of the ingot 102 (e.g., during formation of the neck 142, the cone 144, and/or an initial axial segment of the main body 146) may be too high and lead to unstable ingot growth and poor crystal quality.

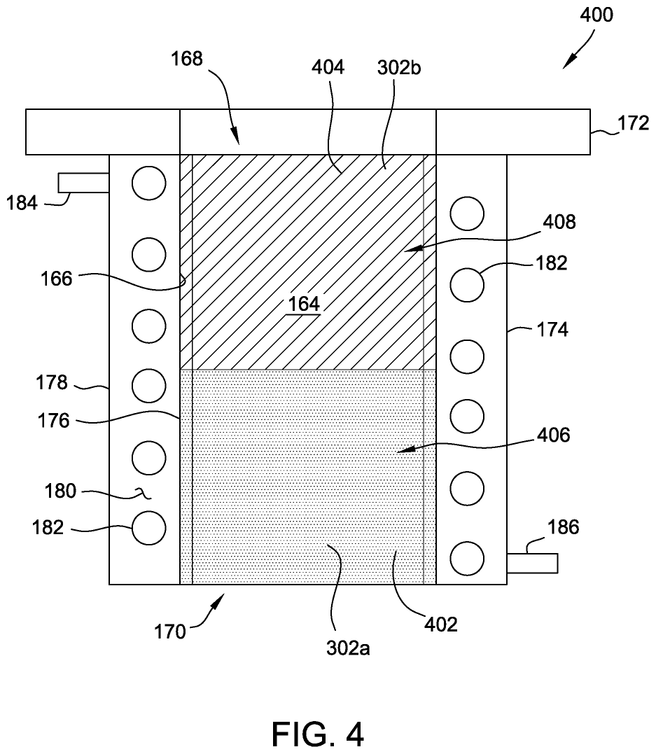

FIG. 4 is an example of the cooling jacket 158, indicated at 400, in which the inner surface 166 is coated with two discrete circumferential bands 402, 404 of the emissive coating material 302. The bands 402 and 404 are vertically stacked between the inlet 170 of the cooling passage 164 and the outlet 168 of the cooling passage 164. A first band 402 defines a first surface region 406 of the inner surface 166 and a second band 404 defines a second surface region 408 of the inner surface 166. The first surface region 406 extends from the inlet 170 of the cooling passage 164 to the second surface region 408, and the second surface region extends to the outlet 168 of the cooling passage 164. The surface regions 406, 408 may each extend vertically approximately one-half the height H₃ of the cooling passage 164. Alternatively, the surface regions 406, 408 may have different vertical extents. For example, the first surface region 406 may extend vertically more than one-half the height H₃, and the second surface region 408 correspondingly extends vertically less than one-half the height H₃. Alternatively, the first surface region 406 may extend vertically less than one-half the height H₃, and the second surface region 408 correspondingly extends vertically more than one-half the height H₃.

In this example, the emissive coating material 302 included in the first band 402, indicated at 302a, has an emissivity coefficient that is different from an emissivity coefficient of the emissive coating material 302 included in the second band 404, indicated at 302b. Compared to the examples in FIGS. 2 and 3, the different emissivity coefficients of the first and second bands 402, 404 provides more variability of the surface emissivity of the inner surface 166, and more flexibility in controlling temperature gradients and cooling rates of the ingot 102 being pulled along the pull axis X₁. This may facilitate better control over transient temperatures and gradients and preventing excessive temperatures and gradients at certain ingot growth stages and vertical locations along the pull axis X₁, and thus reducing or eliminating the propensity for unstable crystal growth and poor crystal quality.

The emissivity coefficients of the emissive coating materials 302a, 302b may differ, for example, by altering the black oxide surface treatments used to form the emissive coating materials 302a, 302b. For example, the black oxide surface treatments used to form the emissive coating materials 302a, 302b may be controlled such that the material densities and/or coating thickness is different between the first and second bands 402, 404, resulting in different emissivity coefficients. Alternatively, the emissivity coefficients of the emissive coating materials 302a, 302b may differ by using different coating patterns in each band 402, 404. For example, one of the bands 402, 404 may include a solid, uniform coating pattern of the emissive coating material 302a, 302b, while the other one of the bands 402, 404 includes a non-uniform coating pattern (e.g., a stippled coating pattern) of the emissive coating material 302a, 302b. In such examples, the solid, uniform coating pattern may result in a larger emissivity coefficient than the non-uniform coating pattern.

In alternative examples of the cooling jacket 400, one or both of the bands 402, 404 may not include (i.e., be free of) an emissive coating material, such that one or both surface regions 406, 408 is an uncoated surface region. In one such example, one of the bands 402, 404 includes the emissive coating material 302 and the other band 402, 404 is a circumferential, uncoated region of the inner surface 166. In this example, the uncoated region may have some degree of roughening to increase the surface emissivity of that region. In another example, both of the bands 402, 404 define discrete, uncoated regions of the inner surface 166. In this example, the uncoated regions defined by the bands 402, 404 may have different degrees of surface roughening to produce the different surface emissivity.

In the examples described above with reference to FIG. 4, both surface regions 406, 408 suitably have a surface emissivity that is greater than the surface emissivity of the inner surface 166. For example, each surface region 406, 408 may have an emissivity coefficient that is at least about 0.3, at least about 0.4, at least about 0.5, at least about 0.6, or at least about 0.7, with the proviso that the surface regions 406, 408 have a different emissivity coefficient. In some examples, one of the surface regions 406, 408 having the relatively lower surface emissivity has an emissivity coefficient between about 0.3 to about 0.75, and the other one of the surface regions 406, 408 having the relatively higher surface emissivity has an emissivity coefficient between about 0.7 to about 0.99. The different emissivity coefficients of the two surface regions 406, 408 may vary within any suitable range to enable the cooling jacket 400 to function as described.

In some examples, the emissivity coefficient of the first surface region 406 is smaller than the emissivity coefficient of the second surface region 408. For example, the first surface region 406 may have an emissivity coefficient between about 0.3 to about 0.75 and the second surface region 408 may have any emissivity coefficient that is larger than the emissivity coefficient of the first surface region 406, for example, between about 0.7 to about 0.99. In these examples, the surface emissivity of the inner surface 166 is relatively lower proximate the inlet 170 of the cooling passage 164 and relatively higher proximate the outlet 168 of the cooling passage 164. The relatively lower surface emissivity proximate the cooling passage inlet 170 may provide sufficient heat transfer to quench the ingot 102 near the solid-melt interface 154 while preventing excessive transient temperatures and gradients at this location that would negatively impact ingot growth and crystal quality. The surface emissivity of the inner surface 166 is relatively higher proximate the outlet 168 of the cooling passage 164, which increases the heat transfer efficiency at vertical locations in the cooling passage 164 that cool the ingot 102 after it has been cooled to a lower temperature. At these locations proximate the cooling passage outlet 168, greater cooling is suitably provided by the cooling jacket 158 to maintain a temperature gradient with the relatively cooler portions of the ingot 102.

Although the example of FIG. 4 shows that the inner surface 166 includes two circumferential bands 402, 404 defining two surface region 406, 408 with different surface emissivity, any number of circumferential bands and different surface regions may be included on the inner surface 166. Increasing the number of surface regions, each having a different surface emissivity, may enable further control over the cooling profile of the ingot 102 by finely tuning temperature gradients between the cooling jacket 158 and the ingot 102 across the cooling passage 164. The vertical lengths of the surface regions having the different surface emissivity may also vary to further control the cooling profile of the ingot 102.

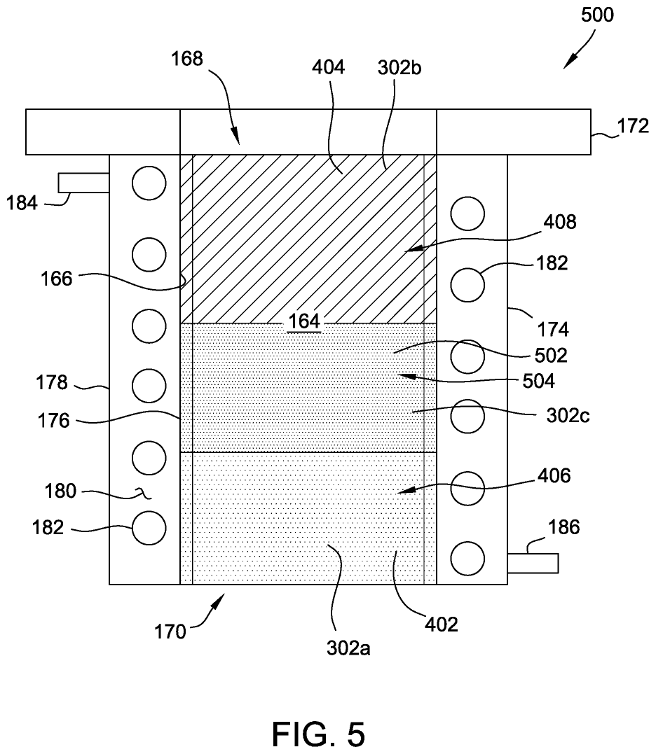

FIG. 5 shows an example of the cooling jacket 158, indicated at 500, in which the inner surface 166 is coated with a third, intermediate circumferential band 502 stacked between the two bands 402, 404 described above for the cooling jacket 400 of FIG. 4. The third band 502 includes the emissive coating material 302, indicated at 302c, and defines a third surface region 504 of the inner surface 166. The third band 502 has a different emissivity coefficient from the first band 402 and from the second band 404. The surface regions 406, 408 and 504 may each extend vertically approximately one-third the height H₃ of the cooling passage 164, or the surface regions 406, 408 and 504 may have different vertical extents.

The surface emissivity of the first surface region 406, the second surface region 408, and the third surface region 504 may differ as described above. In the illustrated example of FIG. 5, each surface region 406, 408, and 504 includes the emissive coating material 302a-c, respectively. In other examples, one or more of the surface regions 406, 408, and 504 may be uncoated. The surface emissivity of two or more uncoated regions may differ depending on a degree of surface roughening as described above.

In the example cooling jacket 500, the first band 402 may have the smallest emissivity coefficient, the second band 404 may have the largest emissivity coefficient, and the intermediate third band 502 may have an emissivity coefficient between the emissivity coefficients of the first and second bands 402, 404. For example, the first band 402 may have an emissivity coefficient that is between about 0.3 to about 0.65, the second band 404 may have an emissivity coefficient that is between about 0.7 to about 0.99, and the third band 502 may have an emissivity coefficient that is between about 0.45 to about 0.75. The different emissivity coefficients of the three surface regions 406, 408, and 504 may vary within any suitable range to enable the cooling jacket 500 to function as described.

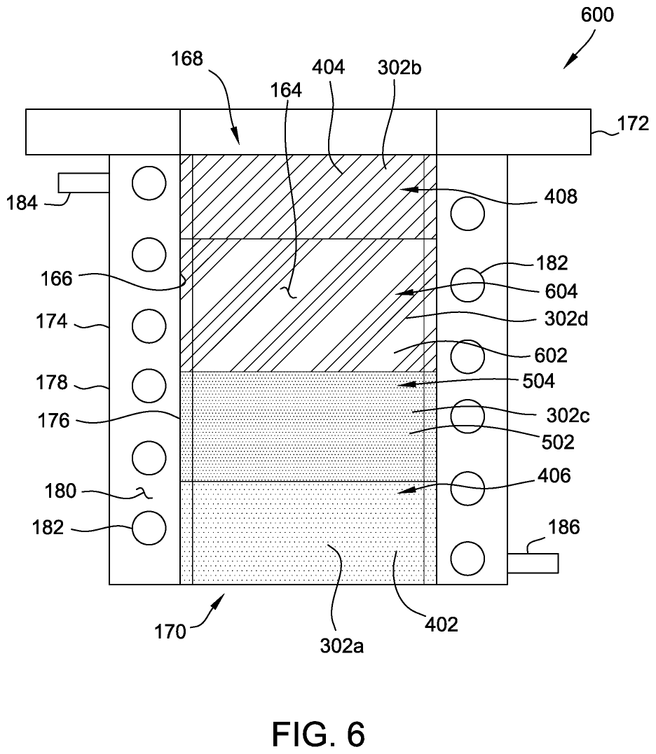

FIG. 6 shows an example of the cooling jacket 158, indicated at 600, in which the inner surface 166 is coated with a fourth, intermediate circumferential band 602 stacked between the third band 502 and the second band 404 described above for the cooling jacket 500 of FIG. 5. The fourth band 602 includes the emissive coating material 302, indicated at 302d, and defines a fourth surface region 604 of the inner surface 166. The fourth band 602 has a different emissivity coefficient from the first band 402, from the second band 404, and from the third band 502. The surface regions 406, 408, 504, 604 may each extend vertically approximately one-fourth the height H₃ of the cooling passage 164, or the surface regions 406, 408, 504, and 604 may have different vertical extents.

The surface emissivity of the first surface region 406, the second surface region 408, the third surface region 504, and the fourth surface region 604 may differ as described above. In the illustrated example of FIG. 6, each surface region 406, 408, 504, and 604 includes the emissive coating material 302a-d, respectively. In other examples, one or more of the surface regions 406, 408, 504, and 604 may be uncoated. The surface emissivity of two or more uncoated regions may differ depending on a degree of surface roughening as described above.

In the example cooling jacket 600, the first band 402 may have the smallest emissivity coefficient, the second band 404 may have the largest emissivity coefficient, and the intermediate third and fourth bands 502 and 602 may each have an emissivity coefficient between the emissivity coefficients of the first and second bands 402, 404. For example, the first band 402 may have an emissivity coefficient that is between about 0.3 to about 0.65, the second band 404 may have an emissivity coefficient that is between about 0.7 to about 0.99, and the third and fourth bands 502, 602 may each have an emissivity coefficient that is between about 0.45 to about 0.75. The fourth band 602 may have a larger emissivity coefficient than the third band 502, such that the surface emissivity of the inner surface 166 increase from the first band 402 towards the second band 404. The different emissivity coefficients of the four surface regions 406, 408, 504, and 604 may vary within any suitable range to enable the cooling jacket 600 to function as described.

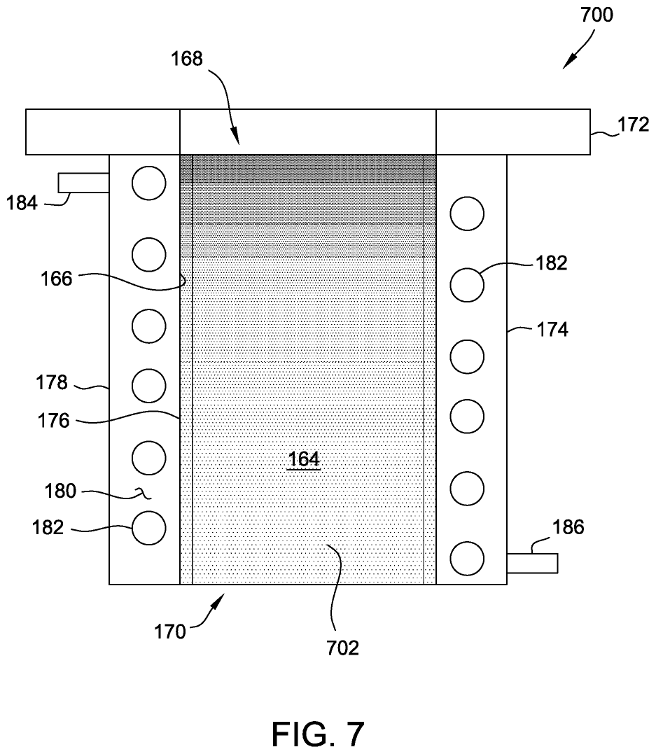

FIG. 7 depicts an example of the cooling jacket 158, indicated at 700, in which the surface emissivity of the inner surface 166 varies continuously between the cooling passage inlet 170 and the cooling passage outlet 168. In this example, rather than including discrete circumferential bands of the emissive coating material 302 (as shown in FIGS. 3-6), the inner surface 166 includes a continuous emissive material coating 702 between the inlet 170 and the outlet 168. In the example shown in FIG. 7, the emissivity coefficient of the emissive material coating 702 gradually increases from the cooling passage inlet 170 towards the cooling passage outlet 168. As such, the surface emissivity of the inner surface 166 is greatest proximate the outlet 168 and smallest proximate the inlet 170. The gradient may be such that the emissivity coefficient of the inner surface steadily increases within a range of about 0.3 to about 0.99. For example, the emissivity coefficient proximate the cooling passage inlet 170 may be in the range of about 0.3 to about 0.5, and the emissivity coefficient steadily increases to within the range of about 0.7 to about 0.99 proximate the cooling passage outlet 168.

The continuous emissive coating material 702 may be formed with the emissivity gradient by controlling the black oxide surface treatments used to form the emissive material coating 702. For example, the black oxide surface treatment may be controlled such that the material density and/or coating thickness gradually increases vertically along the inner surface 166, resulting in a gradually increasing emissivity coefficient. Alternatively, the emissivity coefficient gradient may be formed by gradually changing the coating pattern of the emissive material coating 702. For example, the emissive material coating may gradually change from a non-uniform coating pattern (e.g., a stippled coating pattern) into a solid, uniform coating pattern to steadily increase the emissivity coefficient of the coating 702.

As an alternative to the emissive material coating 702 having the emissivity gradient as shown in FIG. 7, in some examples, the inner surface 166 may have a surface emissivity that gradually changes according to a gradient by steadily increasing a surface roughness of the inner surface 166. For example, to achieve a similar emissivity gradient as the emissive material coating 702, the inner surface 166 may gradually change from a polished or relatively smooth surface proximate the cooling passage inlet 170 into a relatively rough surface proximate the cooling passage outlet 168.

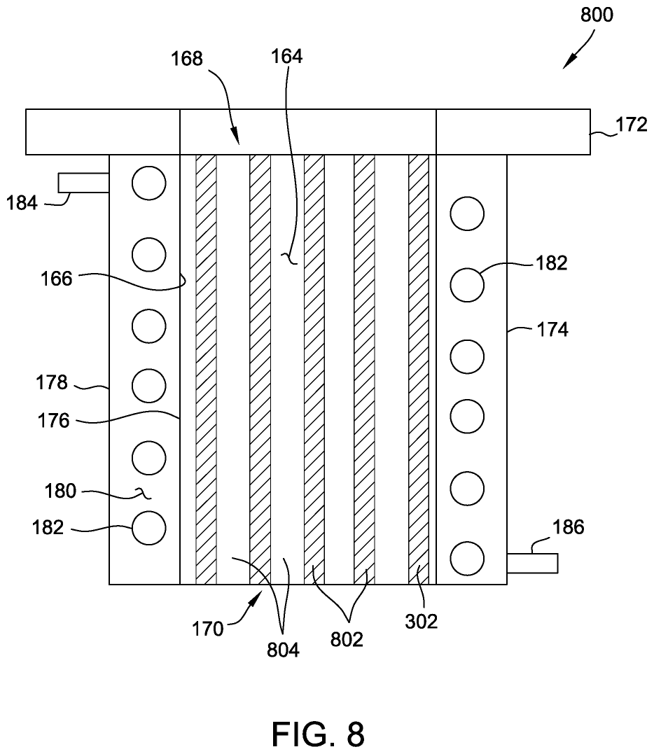

FIG. 8 depicts an example of the cooling jacket 158, indicated at 800, in which the inner surface 166 includes vertical bands 802 of the emissive coating material 302 extending between the cooling passage inlet 170 and the cooling passage outlet 168. The vertical bands 802 have a different (e.g., a larger) emissivity coefficient than the uncoated surface regions 804. As described above, the ingot 102 may be rotated during growth using the pulling assembly 132. This example leverages the rotation of the ingot 102 and circumferentially alternates the surface emissivity of the inner surface 166 between the vertical bands 802 and vertical uncoated surface regions 804 of the inner surface 166. Due to the rotation of the ingot 102 during growth and the circumferential changes in surface emissivity of the inner surface 166, a net cooling of the ingot 102 is provided that is different from the cooling provided by examples of the cooling jacket 158 having an entirely uncoated surface (FIG. 2) and examples of the cooling jacket 158 having an entirely coated surface (FIG. 3). In this example, the vertical bands 802 have a larger emissivity coefficient than the uncoated surface regions 804, such that the cooling achieved by the cooling jacket 800 is greater than the cooling provided by the entirely uncoated inner surface 166 (as shown in FIG. 2) and lower than the cooling provided by the inner surface 166 entirely coated with the emissive coating material 302 (as shown in FIG. 3).

The vertical bands 802 and the uncoated surface regions 804 are discrete vertical regions of the inner surface 166 extending between the inlet 170 and the outlet 168 of the cooling passage 164 and alternate in a circumferential direction relative to the pull axis X₁. The vertical bands 802 and the uncoated surface regions 804 may have approximately the same size, or width, measured in the circumferential direction. Alternatively, the vertical bands 802 may have a smaller or larger width than the uncoated surface regions 804. The size of the vertical bands 802 and uncoated surface regions 804 may vary depending on the desired net surface emissivity of the inner surface 166. In some examples, rather than discrete vertical bands 802 and uncoated surface regions 804, the vertical band 802 may extend continuously across one arcuate portion of the inner surface 166 and the uncoated surface region 804 forms the remaining circumference of the inner surface 166.

In the example cooling jacket 800, the vertical bands 802 of the emissive coating material may have any emissivity coefficient described above for the emissive coating materials with reference to FIGS. 3-7. In some examples, the vertical bands 802 each have an emissivity coefficient between about 0.7 to about 0.99. The emissivity coefficient may vary between the vertical bands 802. For example, some of the vertical bands 802 may have an emissivity coefficient within the range of about 0.7 to about 0.99, and some of the vertical bands 802 may have an emissivity coefficient smaller than 0.7, for example, between about 0.3 to about 0.65. The emissivity coefficient of one, some, or all the vertical bands 802 may also vary between the inlet 170 and the outlet 168 of the cooling passage 164. For example, one, some, or all the vertical bands 802 may have an emissivity coefficient that increases between the inlet 170 and the outlet 168. The variation in the emissivity coefficient for each vertical band 802 may be provided using the techniques described above.

The vertical, uncoated surface regions 804 of the cooling jacket have an emissivity coefficient that is different (e.g., smaller) than the emissivity coefficient of the vertical bands. The emissivity coefficient of the uncoated surface regions 804 may depend on the base material (e.g., steel) of the inner surface 166. For example, the uncoated surface regions 804 may have an emissivity coefficient of smaller than about 0.65, such as between about 0.1 to about 0.65. The emissivity coefficient may also vary between the uncoated surface regions 804. For example, the uncoated surface regions 804 may have varying degrees of surface roughness such that the emissivity coefficient of the uncoated surface regions 804 varies. In some examples, one or some of the uncoated surface regions 804 are relatively polished or reflective and have a relatively smaller emissivity coefficient, such as between about 0.07 to about 0.3, while one or some other of the uncoated surface regions 804 have a relatively rougher surface and have a relatively larger emissivity coefficient, such as between about 0.3 to about 0.7. The emissivity coefficient of one, some, or all the uncoated surface regions 804 may also vary between the inlet 170 and the outlet 168 of the cooling passage 164. For example, one, some, or all the uncoated surface regions 804 may have an emissivity coefficient that increases between the inlet 170 and the outlet 168. The variation in the emissivity coefficient for each uncoated surface region 804 may be provided using the techniques described above.

In the example of FIG. 8, the vertical bands 802 and uncoated surface regions 804 have a relatively constant size, or width measured in the circumferential direction relative to the pull axis X₁. Variations to the net surface emissivity of the inner surface 166 in the vertical direction relative to the pull axis may be provided by changing the emissivity coefficient of the discrete vertical bands 802 and the uncoated surface regions 804 as described above. An additional or alternative way to vary the net surface emissivity of the inner surface 166 that includes the vertical bands 802 is to change the size, or width, of the vertical bands 802 and the uncoated surface regions 804 between the inlet 170 and the outlet 168 of the cooling passage.

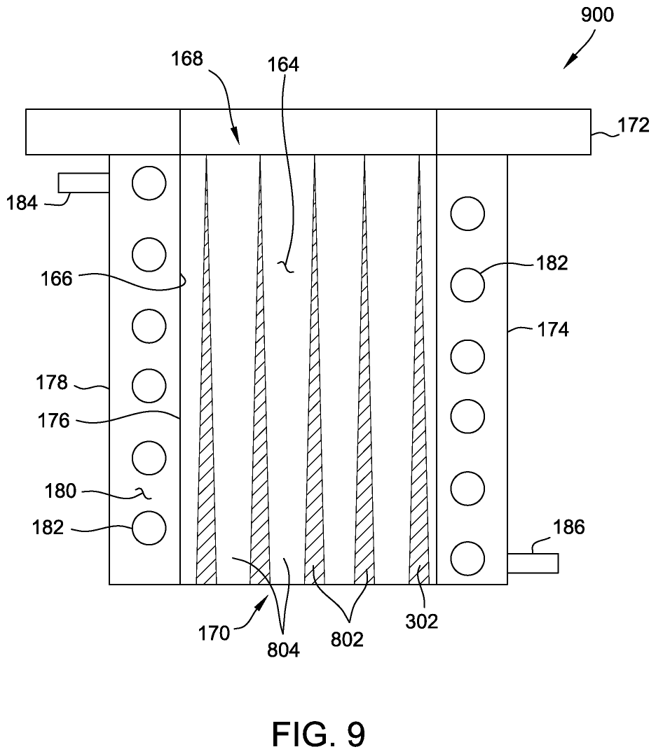

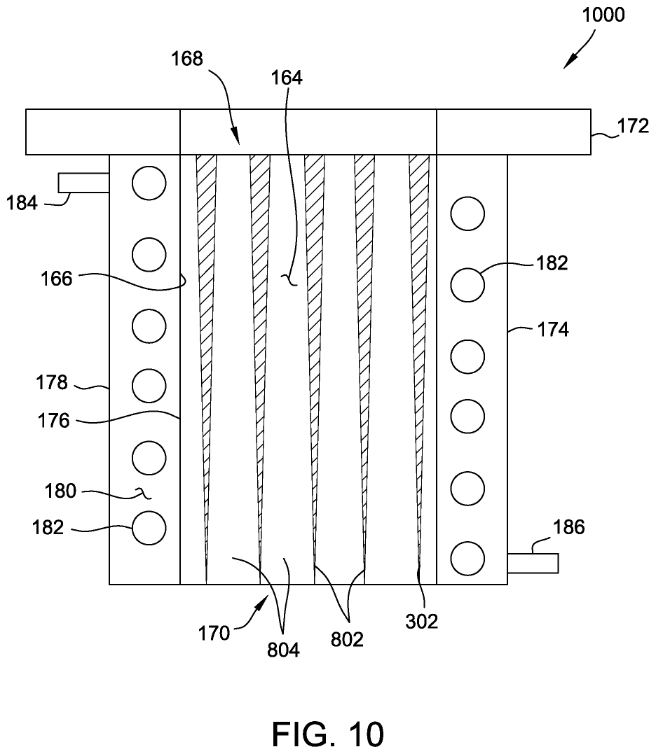

FIGS. 9 and 10 are alternative examples of the cooling jacket 800 of FIG. 8, indicated at 900 and 1000 respectively, in which the vertical bands 802 change in size, or width, between the cooling passage inlet 170 and the cooling passage outlet 168. In the example cooling jacket 900 of FIG. 9, the vertical bands 802 decrease in width in the vertical direction between the inlet 170 and the outlet 168 of the cooling passage 164. Correspondingly, in the example of FIG. 9, the uncoated surface regions 804 increase in width in the vertical direction between the inlet 170 and the outlet 168 of the cooling passage 164. In the example cooling jacket 1000 of FIG. 10, the vertical bands 802 increase in width in the vertical direction between the inlet 170 and the outlet 168 of the cooling passage 164. Correspondingly, in the example of FIG. 10, the uncoated surface regions 804 decrease in width in the vertical direction between the inlet 170 and the outlet 168 of the cooling passage 164. The change in size of the vertical bands 802 along the direction of the pull axis X₁ provides further control of the ingot cooling profile between the cooling passage inlet 170 and the cooling passage outlet 168 by controlling the net surface emissivity of the inner surface 166 in the vertical direction. Further control over the net surface emissivity may be provided by adjusting the emissivity coefficient of the vertical bands 802 and/or the uncoated surface regions 804 in the vertical direction as described above with reference to FIG. 8.

The examples of FIGS. 4-10 provide a number of ways of controlling a cooling profile of the single crystal ingot 102 using different emissivity coefficients of the inner surface 166, that is, varying surface emissivity and heat absorptivity of the cooling jacket 158. The features of these examples can be used in any combination in order to achieve the desired surface emissivity profile of the inner surface 166 for controlling the cooling profile of the ingot 102. In various examples, the surface emissivity profile of the inner surface 166 facilitates controlling local temperature gradients and cooling rates between the single crystal ingot 102 and the cooling jacket 158 during growth of the ingot 102 at various different vertical locations and/or different stages of the ingot growth process. In some examples, a first surface region of the inner surface 166 proximate the cooling passage inlet 170 has an emissivity coefficient (e.g., between about 0.3 to about 0.75) that enables rapid cooling of the ingot 102 proximate the solid-melt interface 154 without generating excessive transient temperatures and gradients that negatively impact ingot growth and crystal quality. In these examples, one or more surface regions of the inner surface 166 above the first surface region have emissivity coefficients that are different from the emissivity coefficient of the first surface region, and facilitate controlling one or more temperature gradients and cooling rates between the cooling jacket 158 and the single crystal ingot 102 as the ingot 102 is being pulled through the cooling passage 164. The emissivity coefficient of the surface regions above the first surface region may vary within the range of about 0.5 to about 0.99, and may increase in the vertical direction such that the emissivity coefficient proximate the cooling passage outlet 168 is in the range of about 0.7 to about 0.99. In some examples, in addition to or in the alternative to varying the surface emissivity of the inner surface in the vertical direction, the inner surface 166 may have an alternating surface emissivity in the circumferential direction that operates in conjunction with ingot rotation during growth to control the cooling profile of the ingot.

As described above, an example cooling profile of the ingot 102 includes a rapid cooling or quenching stage to solidify the ingot 102 (e.g., at or below about 1100° C. for silicon ingots) near the solid-melt interface 154 and prevent lateral incorporation of defects, followed by controlled cooling of the ingot 102 to the defect nucleation temperature (e.g., about 900° C. for silicon ingots) to allow for controlled inward diffusion and even distribution of defects in the ingot 102, and finally cooling the ingot to a temperature as low as, for example, about 600° C. to inhibit transport, growth, and/or agglomeration of defects in the ingot 102. In the examples described above with reference to FIGS. 4-10, the surface emissivity of the inner surface 166 may be fine-tuned according to this cooling profile, and facilitates maximizing control over the various transport and nucleation mechanisms of defects at various stages of crystal growth without generating excessive transient temperatures and gradients that can negatively impact crystal growth and crystal quality. This facilitates reducing the size and concentration of defects grown into the ingot 102 without sacrificing crystal quality and stable ingot growth, and doing so using a repeatable, cost-effective approach that minimizes complexity of the cooling jacket 158.

Examples of the cooling jacket 158 will now be described in which the cooling jacket 158 is moveable within the growth chamber 110 to facilitate controlling cooling profiles of the ingot 102 using changes to the view factor F between the cooling jacket 158 and the ingot 102. As described above, an increase in the view factor F means that a greater amount of cooling power reaches the ingot 102, and thus increasing the view factor F increases the cooling rate. The view factor F can be controlled independent of or in conjunction with controlling the surface emissivity of the inner surface 166. In this regard, the features of any example cooling jacket 158 described above with reference to FIGS. 3-10 can be implemented in combination with the features of the moveable cooling jackets described below.

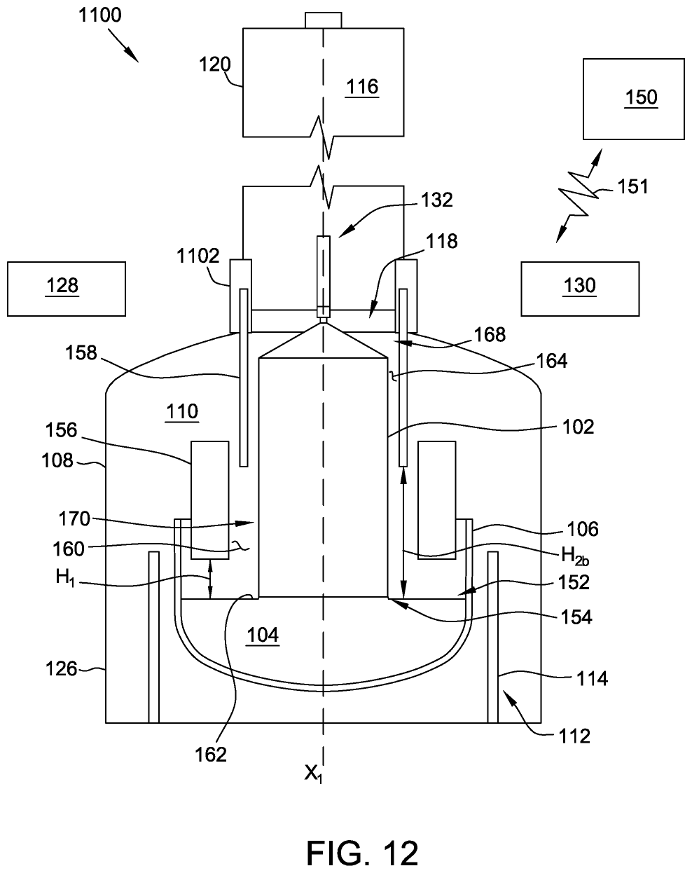

Referring now to FIGS. 11 and 12, another example ingot puller apparatus or ingot puller is indicated generally at 1100. The ingot puller 1100 includes the same features and components as the ingot puller 100, indicated using the same reference numerals. Various components of the ingot puller 100, 1100 are not labeled in FIGS. 11 and 12 for ease of illustration and description. The above-description of the ingot puller 100 applies equally to the ingot puller 1100 unless expressly stated otherwise or the context clearly indicates otherwise.

In this example, the ingot puller 1100 also includes an actuator 1102 connected to the cooling jacket 158 and operable to move the cooling jacket in the growth chamber 110. In particular, the actuator 1102 is operable to raise and lower the cooling jacket 158 along the pull axis X₁, thereby adjusting the height H₂ between the inlet 170 of the cooling passage 164 and the surface 162 of the melt 104. FIG. 11 shows the cooling jacket 158 in a lowered position, at a first height H₂ₐ above the melt surface 162. FIG. 12 shows the cooling jacket 158 in a raised position, at a second height H_{2b} above the melt surface 162. The second height H_{2b} is taller than the first height H₂ₐ.

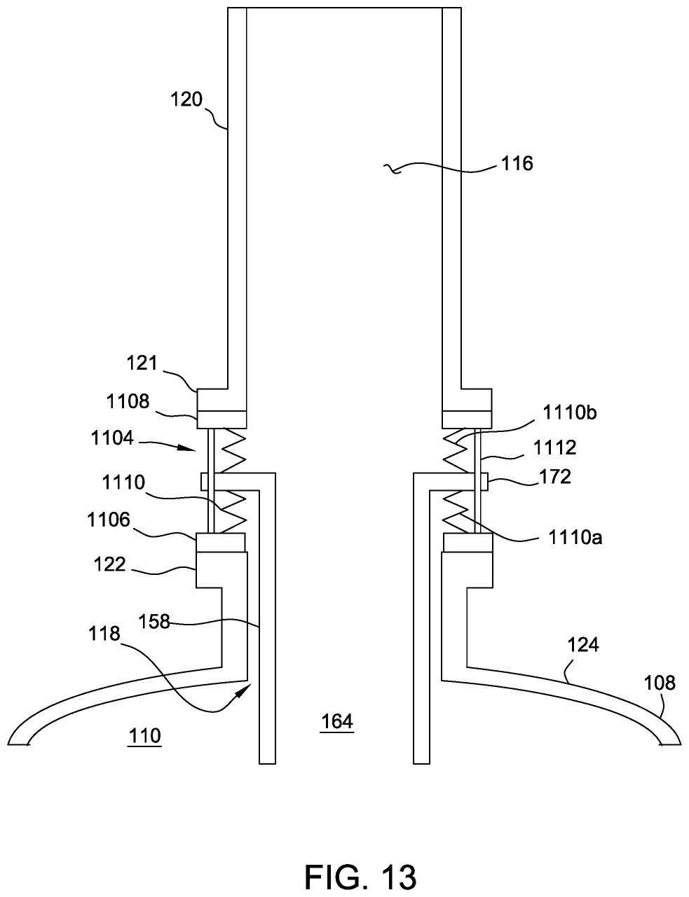

The actuator 1102 may include any suitable mechanical actuator operable to raise and lower the cooling jacket 158 in the growth chamber 110. For example, the actuator 1102 may include hydraulic cylinder(s), pneumatic cylinder(s), a linear or servo motor, a bellows, and the like. Referring to FIG. 13, in one example, the actuator 1102 includes a bellows 1104 positioned outside the growth chamber 110. The bellows 1104 expands and contracts to respectively lower and raise the cooling jacket 158 in the growth chamber. The bellows 1104 may include a structural metal material, such as steel for example.

In the illustrated example, the bellows 1104 is positioned between the outlet flange 122 of the housing 108 and the tubular vessel 120. The bellows 1104 includes a first flange 1106 connected to the outlet flange 122 and a second flange 1108 connected to a tubular vessel flange 121. The tubular vessel flange 121 defines an inlet of the ingot removal chamber 116. The bellows 1104 includes a flexible, tubular body 1110 connected to the first and second flanges 1106, 1108. The body 1110 expands and contracts for moving the cooling jacket 158 in the growth chamber 110. The body 1110 defines a central passage coaxially aligned with the outlet 118 of the growth chamber 110 and the ingot removal chamber 116. The central passage defined by the body 1110 is sized to enable the ingot 102 to be pulled therethrough. For example, the central passage defined by the body 1110 may have approximately the same diameter as the growth chamber outlet 118 and/or the ingot removal chamber 116.

The bellows 1104 also includes guide rails 1112 that extend between the first and second flanges 1106, 1108. The guide rails 1112 are located radially outward of the flexible body 1110. Any number of guide rails 1112 may be included, such as two or more guide rails 1112. The cooling jacket flange 172 is slidingly positioned on the guide rails 1112 and connected to the flexible body 1110. As the flexible body 1110 expands and contracts, the cooling jacket flange 172 slides along the guide rails 1112 between the housing 108 and the tubular vessel 120, thereby allowing movement of the cooling jacket 158 in the growth chamber 110.

Because the flexible body 1110 of the bellows 1104 defines a passage through which the ingot 102 is pulled into the ingot removal chamber 116, the body 1110 forms a vacuum seal between the flanges 1106, 1108 and the cooling jacket flange 172 to prevent contaminants from infiltrating the ingot 102. The flexible body 1110 includes a first body segment 1110a connected between the first flange 1106 and the cooling jacket flange 172, and a second body segment 1110b between the cooling jacket flange 172 and the second flange 1108. The body segments 1110a, b form vacuum seals between the cooling jacket flange 172 and the respective flange 1106, 1108.

Referring to FIGS. 11 and 12, the actuator 1102 (e.g., the bellows 1104) is connected to the controller 150 which causes the actuator 1102 to move the cooling jacket 158 in the growth chamber 110. As described above, the controller 150 is also connected to the pyrometer 128 and the IR camera 130 and receives feedback and monitored process information of conditions within the growth chamber 110, such as the temperature of the melt 104, temperature at the solid-melt interface 154, surface level of the melt 104 (i.e., a vertical position of the melt surface 162), the temperature of the ingot 102, among other information. The controller 150 may control the position of the cooling jacket 158 based on the monitored information received from the pyrometer 128 and/or the IR camera 130. For example, the controller 150 may control movement of the cooling jacket 158 to maintain and/or the height H₂ of the cooling jacket 158 from the surface of the melt 104 detected by the IR camera 130. Additionally or alternatively, the controller may control movement of the cooling jacket 158 depending on a measured temperature of the ingot 102 and/or melt 104 (e.g., a temperature adjacent the solid-melt interface 154) to increase or decrease cooling of the ingot 102 by changing the view factor F between the cooling jacket 158 and the ingot 102.

Movement of the cooling jacket 158 in the growth passage 110 provides more variability and flexibility to the height H₂ of the cooling jacket 158 from the melt surface 162. When the cooling jacket 158 is stationary in the growth chamber 110, the range of suitable heights H₂ of the cooling jacket 158 may be relatively limited since the cooling jacket 158 remains at that height throughout the entire ingot growth process (and thus, the height H₂ must be appropriate for initial, intermediate, and late-stage ingot growth). For example, the height H₂ of the cooling jacket 158 from the melt surface 162 may be in the range of about 140 mm to about 160 mm when the cooling jacket 158 is stationary. In the example of FIGS. 11 and 12, the height H₂ of the moveable cooling jacket 158 may vary across a much wider range, for example, in the range of about 125 mm to about 275 mm. In particular, the cooling jacket 158 may be moved to a relatively taller heights H_{2b} (e.g., between about 175 mm to about 275 mm) at certain stages of the ingot growth process and a relatively shorter height H₂ₐ (e.g., between about 125 mm to about 175 mm) at other stages of the ingot growth process, depending on the particular cooling profile desired at that stage. For example, at initial stages of the ingot growth process, the cooling jacket 158 may be moved to the relatively taller height H_{2b} to prevent excessive temperatures and gradients during early stage growth, and after some axial length of the ingot 102 has grown, the cooling jacket 158 may be moved to the relatively shorter height H₂ₐ. Over the course of the ingot growth process, the height H₂ may change by about 10 mm, about 25 mm, about 50 mm, about 100 mm, or by more than 100 mm.

Referring briefly to the examples described above for FIGS. 4-10, adjusting the surface emissivity of the cooling jacket 158 may also allow a wider range for the height H₂. For example, by controlling the surface emissivity of the cooling jacket 158 at the inlet 170 of the cooling passage 164, the cooling jacket 158 may be positioned at a shorter height H₂ without generating excessive transient temperatures and gradients that negatively impact ingot growth and quality. Alternatively, the surface emissivity of the cooling jacket 158 at the inlet 170 of the cooling passage 164 may be increased such that the cooling jacket 158 can be at a taller height H₂ from the melt surface 162 while still providing adequate cooling to quench the ingot 102 proximate the solid-melt interface 154. In these examples, when the cooling jacket 158 is stationary in the growth chamber 110, the height H₂ may be in the range of about 125 mm to about 200 mm.

Referring again to FIGS. 11 and 12, in some examples the controller 150 controls movement of the cooling jacket 158 to adjust the height H₂ from the melt surface 162 to predetermined distances at one or more stages of growth of the single crystal ingot 102. For example, the controller 150 may store in memory predetermined routines for controlling movement of the cooling jacket 158 during the ingot growth process. In one example, the predetermined routine includes positioning the cooling jacket 158 at the height H_{2b} at the beginning of the ingot growth process. After a predetermined axial length (e.g., 10 mm, 25 mm, 50 mm, 75 mm, or more than 75 mm) of the ingot 102 has been grown, or after a predetermined duration or some other predetermined criteria has been met, the controller 150 lowers the cooling jacket 158 to the height H₂ₐ. The cooling jacket 158 may remain at the height H₂ₐ for the remainder of the growth process, or may be moved (lowered or raised) to one or more other predetermined heights H₂ depending on the routine.

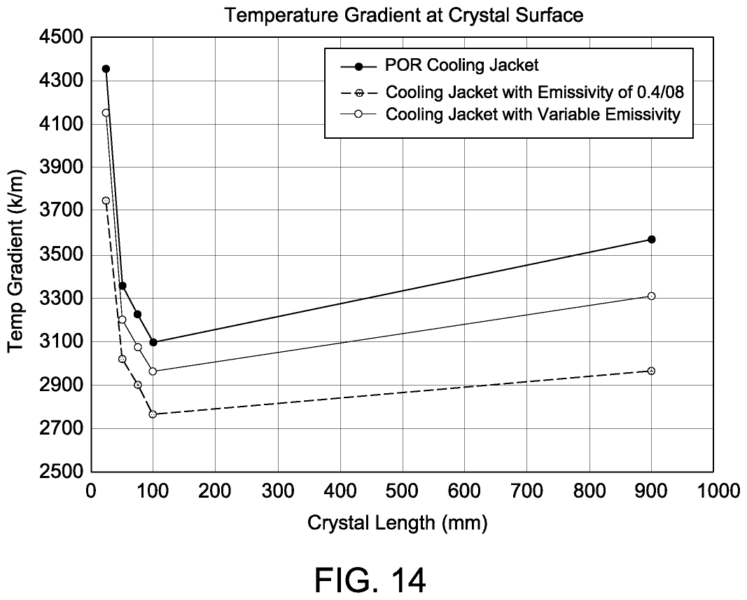

In some examples, the controller 150 controls movement of the cooling jacket 158 to adjust the height H₂ from the melt surface 162 according to a predetermined movement profile for controlled cooling of the ingot 102. The predetermined movement profile may be generated using thermal simulations and/or empirical temperature and gradient measurements taken during ingot growth processes. Example thermal simulations that may be used to generate the predetermined movement profile are described below in Examples 1 and 2 and with reference to FIGS. 14-18. The predetermined movement profile may include information regarding stages of ingot growth during which the cooling jacket 158 should be positioned at a raised height H_{2b} to prevent against excessive transient temperatures and gradients at early stages of ingot growth near the solid-melt interface 154, as well as stages of ingot growth at which the cooling jacket 158 can be positioned at a lowered height H₂ₐ without generating excessive transient temperatures and gradients.

The predetermined movement profile according to which the cooling jacket 158 is moved by the controller 150 may also include information regarding the height H₂ at which the cooling jacket 158 should be positioned to achieve constant temperature gradients and cooling rates at one or more vertical locations along the pull axis X₁. For example, the predetermined movement profile may include information regarding the height H₂ at which the cooling jacket 158 should be positioned at each stage of the growth process to maintain a substantially constant temperature gradient between the cooling jacket 158 and the single crystal ingot 102 proximate the solid-melt interface 154 during growth of the single crystal ingot 102. Additionally or alternatively, the predetermined movement profile may include information regarding the height H₂ at which the cooling jacket 158 should be positioned at each stage of the growth process to maintain a substantially constant temperature gradient between the cooling jacket 158 and the single crystal ingot 102 at one or more vertical locations in the cooling passage 164 during growth of the single crystal ingot 102. Additionally or alternatively, the predetermined movement profile may include information regarding the height H₂ at which the cooling jacket 158 should be positioned at each stage of the growth process to maintain a substantially constant temperature gradient between the cooling jacket 158 and the single crystal ingot 102 at different body length positions of the ingot 102 (i.e., different axial positions of the ingot 102 relative to the melt 104) during growth. Additionally or alternatively, the predetermined movement profile may include information regarding the height H₂ at which the cooling jacket 158 should be positioned at each stage of the growth process to maintain a substantially constant temperature gradient between the cooling jacket 158 and the single crystal ingot 102 at ingot temperatures of between 600° C. to 1415° C., such as at 900° C., 1000° C., 1100° C., 1200° C., and/or 1300° C.

In some examples, in addition to or in the alternative to the predetermined movement profile, the controller 150 dynamically controls movement of the cooling jacket 158 based on one or more measured parameters in the growth chamber 110 obtained from one or more sensors (e.g., the pyrometer 128 and/or the IR camera 130). In such examples, the controller 150 may control movement of the cooling jacket 158 using closed-loop feedback control based on the measured parameter(s). The one or more measured parameters may include a measured temperature of the ingot 102. The measured temperature may be obtained from the outer surface 148 of the ingot 102 at one or more body length locations using the pyrometer 128. Using the measured parameter as feedback, the controller 150 may determine whether the cooling jacket 158 should be raised or lowered to adjust the temperature gradient and cooling rate. For example, the controller 150 may determine that, based on a measured temperature near the solid-melt interface 154, that an excessive temperature gradient exists and, in response, raises the cooling jacket 158 to reduce the temperature gradient at that location. By continuously or periodically monitoring the parameter(s) in the growth chamber 110 (e.g., temperature), the controller 150 can dynamically adjust the height H₂ of the cooling jacket 158 to achieve the desired cooling profile of the ingot 102. For example, once the temperature near the solid-melt interface 154 is reduced, the controller 150 may lower the cooling jacket 158 to increase the temperature gradient at that location.

The ingot puller apparatus and cooling jackets described herein provide several advantages over known ingot pulling systems and methods by controlling surface emissivity of the cooling jacket and/or a view factor between the cooling jacket and the ingot to facilitate controlling various stages of the ingot growth and cooling process. In particular, embodiments described facilitate improving control over ingot cooling profiles which can be finely tuned to reduce the size and concentration of defects that form in single crystal ingots. At the various stages of the ingot growth process, defects in the ingot undergo various transport and nucleation mechanisms, and the cooling jackets described provide controlled temperature gradients and cooling rates to leverage these mechanisms at their respective stages and thereby reduce the size and/or concentration of defects incorporated into the ingot during growth.

### EXAMPLES

The following non-limiting examples are provided to further illustrate the present disclosure. It should be appreciated by those of skill in the art that the techniques disclosed in the examples that follow represent approaches the inventors have found function well in the practice of the present disclosure, and thus can be considered to constitute examples of modes for its practice. However, those of skill in the art should, in light of the present disclosure, appreciate that many changes can be made in the specific embodiments that are disclosed and still obtain a like or similar result without departing from the spirit and scope of the present disclosure.

### Example 1. Thermal Simulation Results of Cooling Jackets with Varying Surface Emissivity

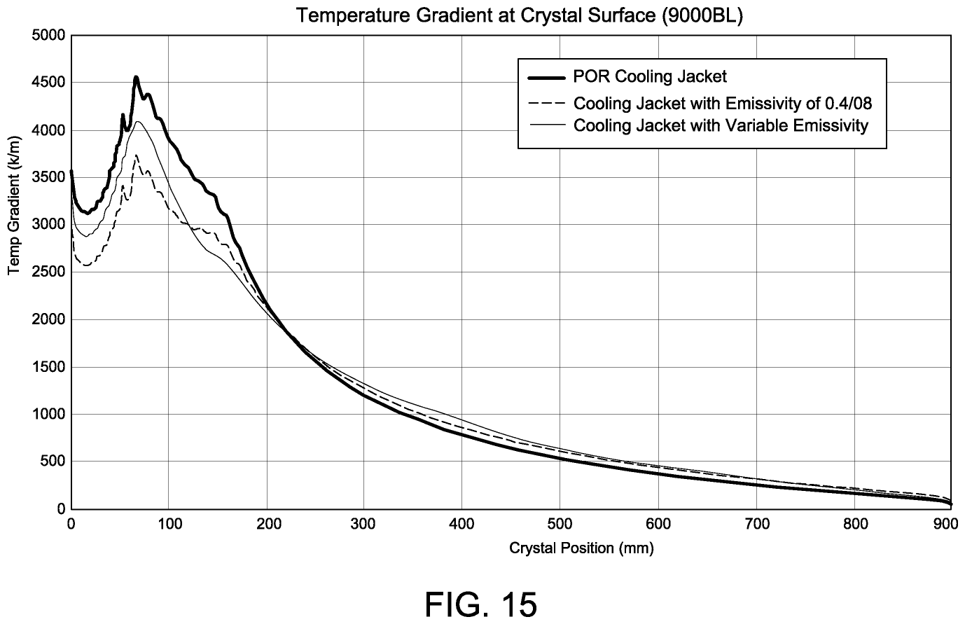

Thermal simulation results of temperature gradients within a growth chamber were obtained across multiple ingot growth processes using three different cooling jacket configurations in which the surface emissivity was varied. The results are shown in FIGS. 14 and 15, described in more detail below. The “POR Cooling Jacket” configuration is a cooling jacket that includes an inner surface that was uniformly coated with an emissive coating material having an emissivity coefficient of about 0.8. The “Cooling Jacket with Emissivity of 0.4/0.8” configuration is a two-band cooling jacket that include an inner surface that was half-coated, proximate the inlet of the cooling passage, with an emissive coating material having an emissivity coefficient of about 0.4 and half-coated, proximate the outlet of the cooling passage, with an emissive coating material having an emissivity coefficient of about 0.8. The “Cooling Jacket with Variable Emissivity” configuration is a three-band cooling jacket that includes an inner surface with three emissive coatings, one proximate the inlet of the cooling passage having an emissivity coefficient of about 0.4 and extending about ¼ the length of the cooling passage, one proximate the outlet of the cooling passage having an emissivity coefficient of about 0.8 extending about ¼ the length of the cooling passage, and one intermediate coating having an emissivity coefficient of about 0.6 and extending about ½ the length of the cooling passage.

FIG. 14 is a plot of simulated temperature gradients between a surface of an ingot at a solid-melt interface and the cooling jacket for the three different cooling jacket configurations. The temperature gradients were measured at different stages of the ingot growth process across multiple different growth processes. Every dot represents a simulated surface temperature of the outer surface of ingot proximate the solid-melt interface at a certain ingot length. Several ingot growth processes were performed and simulated measurements taken at the solid-melt interface location at stages where the ingot was grown a length of 25 mm body length, 50 mm body length, 100 mm body length, and 900 mm body length to construct this plot. As shown in FIG. 14, the POR Cooling Jacket can produce the highest overall temperature gradient in the entire growth range but the initial temperature gradients at the early part of crystal growth are too high. The two-band cooling jacket can produce significantly reduced gradients at the early part of ingot growth and the gradients at later body growth are also significantly reduced. The three-band cooling jacket can produce gradients in between the POR Cooling Jacket and the two-band cooling jacket.

FIG. 15 is a plot of simulated temperature gradients between a surface of an ingot and the cooling jacket, measured at different body length positions of the ingot, for the three different cooling jacket configurations used in FIG. 14. All three configurations were simulated across 900 mm ingot body length. As shown in FIG. 15, the POR Cooling Jacket creates very high temperature gradient changes at the early body length between 0 to 200 mm body, and peaked at about 80 mm body length when the crystal enters the cooling passage of the cooling jacket. The two-band cooling jacket can produce significantly reduced gradient changes at the very early part of crystal growth and the three-band cooling jacket can produce gradients in between the POR Cooling Jacket and the two-band cooling jacket.

Thus, FIGS. 14 and 15 demonstrate that increasing the number of bands, or using continuous band with an emissivity gradient, to vary the surface emissivity of the cooling jacket can provide better control over temperature gradients and allow for fine-tuning the cooling profile of the ingot.

### Example 2. Thermal Simulation Results of Moveable Cooling Jackets

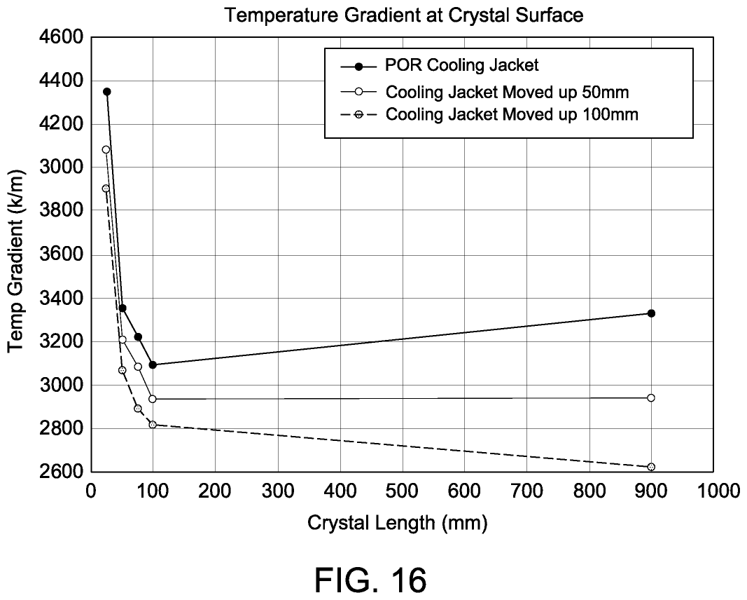

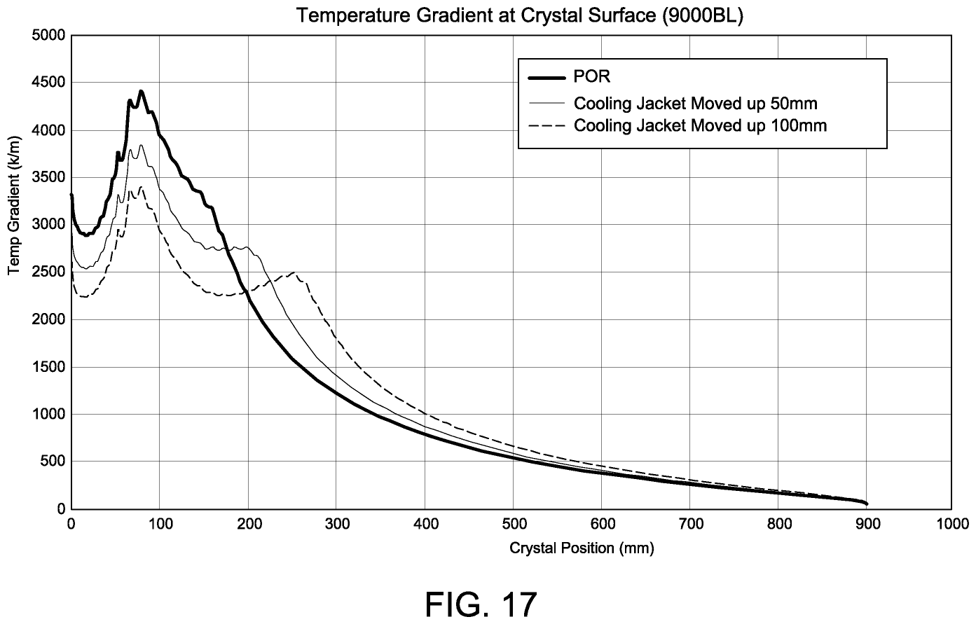

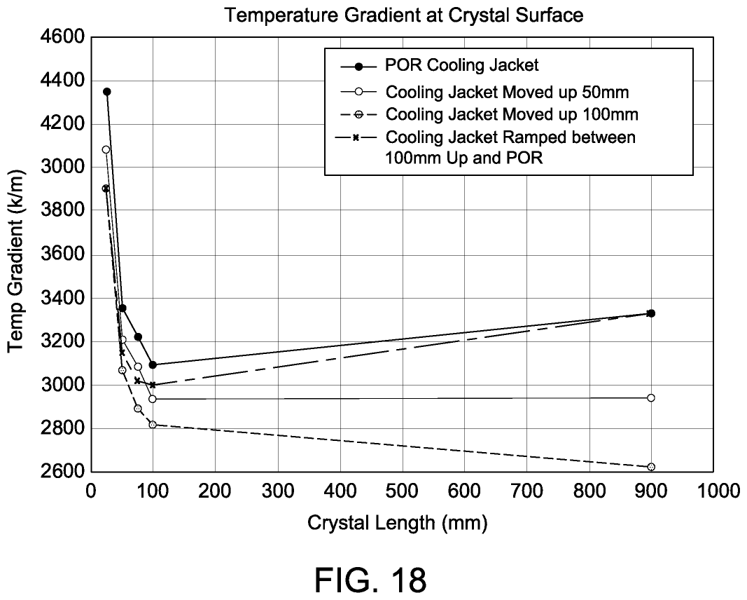

Thermal simulation results of temperature gradients within a growth chamber were obtained across multiple ingot growth processes using different cooling jacket configurations in which the position of the cooling jacket in the growth chamber was varied. The results are shown in FIGS. 16-18, described in more detail below. The “POR Cooling Jacket” configuration is a cooling jacket that is positioned at a fixed height between 140 mm to about 160 mm above the surface of the melt. The fixed height was increased by 50 mm and by 100 mm and the results of those configurations are also recorded in FIGS. 16-18. FIGS. 17 and 18 also include results for a cooling jacket that was initially positioned 100 mm above the height of the POR Cooling Jacket for a ramp period, and then was lowered to the POR Cooling Jacket height after a length of the ingot had been grown.

The simulated results in FIGS. 16 and 18 were generated similar to those of FIG. 14 described above. The simulated results in FIG. 17 were generated similar to those of FIG. 15 described above.

As shown in FIG. 16, the POR fixed cooling jacket height produces the highest overall temperature gradient in the entire growth range but the initial temperature gradients at the early part of ingot growth are too high. Raising the cooling jacket by 100 mm compared to the POR height can produce significantly reduced temperature gradients at the early part of crystal growth and the temperature gradients at later body growth are also significantly reduced. Raising the cooling jacket by 50 mm compared to the POR height can produce gradients in between the POR height and the 100 mm above the POR height case.

Moving the cooling jacket to different position at different crystal length following a pre-determined ramp profile can modify and optimize the temperature gradients at different body lengths of the ingot. The thermal simulation result of an example of ramped profile is illustrated in FIG. 17, in which the cooling jacket was initially raised to 100 mm above the POR height and then lowered to the POR height following a pre-determined ramp over which a length of the ingot was grown. By following this pre-determined ramp profile, the cooling jacket can deliver reduced temperature at the very beginning of the ingot body, which is around 0 mm ingot body length, a smoother temperature transient from 25 mm to 100 mm ingot body length, as well as maximized temperature from 100 mm through the rest of ingot growth. FIG. 18 illustrates another representation of the pre-determined ramp mechanism of FIG. 17 and the ability to control gradients by adjusting the height of the cooling jacket during ingot growth.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

Unless otherwise indicated, approximating language, such as “generally,” “substantially,” and “about,” as used herein indicates that the term so modified may apply to only an approximate degree, as would be recognized by one of ordinary skill in the art, rather than to an absolute or perfect degree. Accordingly, a value modified by a term or terms such as “about,” “approximately,” and “substantially” is not to be limited to the precise value specified. In at least some instances, the approximating language may correspond to the precision of an instrument for measuring the value. Additionally, unless otherwise indicated, the terms “first,” “second,” etc. are used herein merely as labels, and are not intended to impose ordinal, positional, or hierarchical requirements on the items to which these terms refer. Moreover, reference to, for example, a “second” item does not require or preclude the existence of, for example, a “first” or lower-numbered item or a “third” or higher-numbered item.

As used herein, the terms “processor” and “computer” and related terms, e.g., “processing device,” “computing device,” and “controller” are not limited to just those integrated circuits referred to in the art as a computer, but instead refer broadly to a microcontroller, a microcomputer, a programmable logic controller (PLC), an application specific integrated circuit, and/or other programmable circuits, and such terms are used interchangeably herein. In the embodiments described herein, memory may include, but is not limited to, a computer-readable medium, such as a random access memory (RAM), and a computer-readable non-volatile medium, such as Alternatively, a floppy disk, a compact disc flash memory-read only memory (CD-ROM), a magneto-optical disk (MOD), and/or a digital versatile disc (DVD) may also be used. Also, in the embodiments described herein, additional input channels may be, but are not limited to only being, computer peripherals associated with an operator interface such as a mouse and a keyboard. Alternatively, other computer peripherals may also be used such as, but not limited to, a scanner. Furthermore, in the embodiments described herein, additional output channels may include, but are not limited to only being, an operator interface monitor.

As various changes could be made in the above constructions and methods without departing from the scope of the invention, it is intended that all matter contained in the above description and shown in the accompanying drawings shall be interpreted as illustrative and not in a limiting sense.

1. An ingot puller apparatus for producing a single crystal ingot, the ingot puller apparatus comprising:
a housing defining a growth chamber and a growth chamber outlet;
a crucible positioned in the growth chamber for containing a melt of semiconductor material;
a cooling jacket positioned in the growth chamber between the crucible and the growth chamber outlet, the cooling jacket comprising an inner surface defining a cooling passage having an inlet proximate the crucible and an outlet proximate the growth chamber outlet; and
a puller positioned to pull the single crystal ingot from the melt and through the cooling passage,
wherein the inner surface of the cooling jacket comprises a first surface region having a first emissivity coefficient and a second surface region having a second emissivity coefficient larger than the first emissivity coefficient to control a cooling profile of the single crystal ingot.

2. The ingot puller apparatus of claim 1, wherein the first emissivity coefficient is less than 0.75 and the second emissivity coefficient is greater than 0.7, with the proviso that the second emissivity coefficient is larger than the first emissivity coefficient.

3. The ingot puller apparatus of claim 1, wherein the first and second surface regions each include an emissive coating material.

4. The ingot puller apparatus of claim 3, wherein the emissive coating material of each surface region is a black oxide material.

5. The ingot puller apparatus of claim 1, wherein the first and second surface regions are discrete circumferential surface regions stacked between the inlet and outlet of the cooling passage.

6. The ingot puller apparatus of claim 5, wherein the first surface region is proximate the inlet of the cooling passage and the second surface region is proximate the outlet of the cooling passage.

7. The ingot puller apparatus of claim 5, wherein the inner surface further comprises a third discrete circumferential surface region between the first surface region and the second surface region, wherein the third surface region has a larger emissivity coefficient than the first surface region and a smaller emissivity coefficient than the second surface region.

8. The ingot puller apparatus of claim 5, wherein the inner surface further comprises intermediate discrete circumferential surface regions between the first surface region and the second surface region, wherein an emissivity coefficient of the intermediate surface regions increases from the first surface region towards the second surface region.

9. The ingot puller apparatus of claim 1, wherein the inner surface has a continuous emissivity gradient between the first surface region and the second surface region such that the emissivity coefficient of the inner surface is largest at the second surface region and smallest at the first surface region.

10. The ingot puller apparatus of claim 9, wherein the first surface region is proximate the inlet of the cooling passage and the second surface region is proximate the outlet of the cooling passage.

11. The ingot puller apparatus of claim 1, wherein the first surface region includes an emissive coating material and the second surface region is an uncoated region of the inner surface.

12. The ingot puller apparatus of claim 11, wherein the first surface region and the second surface region extend between the inlet and outlet of the cooling passage, and wherein the puller is configured to rotate the single crystal ingot in the cooling passage.

13. The ingot puller apparatus of claim 12, wherein the first surface region and the second surface region vary in size between the inlet and outlet of the cooling passage.

14. The ingot puller apparatus of claim 13, wherein the first surface region increases in size towards the outlet of the cooling passage and the second surface region correspondingly decreases in size towards the outlet of the cooling passage.

15. The ingot puller apparatus of claim 13, wherein the second surface region increases in size towards the outlet of the cooling passage and the first surface region correspondingly decreases in size towards the outlet of the cooling passage.

16. The ingot puller apparatus of claim 12, wherein the first surface region and the second surface region each include discrete regions of the inner surface extending between the inlet and outlet of the cooling passage and alternating in a circumferential direction.

17. The ingot puller apparatus of claim 11, wherein the second surface region has varying degrees of surface roughness such that an emissivity coefficient of the second surface region varies.

18. A method of producing a single crystal ingot, the method comprising:
preparing a melt of semiconductor material in a crucible positioned in a growth chamber of an ingot puller apparatus;
contacting the melt with a seed crystal;
pulling the seed crystal from the melt to grow the single crystal ingot;
cooling the single crystal ingot during growth using a cooling jacket positioned in the growth chamber, wherein the single crystal ingot is pulled through a cooling passage defined by an inner surface of the cooling jacket; and
controlling a cooling profile of the single crystal ingot using different emissivity coefficients of the inner surface.

19. The method of claim 18, wherein controlling the cooling profile of the single crystal ingot comprises controlling local temperature gradients between the single crystal ingot and the cooling jacket during growth using a first emissivity coefficient of a surface region of the inner surface proximate the inlet of the cooling passage and a second emissivity coefficient of a surface region of the inner surface proximate the outlet of the cooling passage.

20. The method of claim 19, wherein controlling the cooling profile of the single crystal ingot comprises controlling a temperature gradient between the cooling jacket and the single crystal ingot adjacent a melt-solid interface during growth using the first emissivity coefficient and controlling a temperature gradient between the cooling jacket and the single crystal ingot in the cooling passage using the second emissivity coefficient.

21. The method of claim 18, further comprising rotating the single crystal ingot in the cooling passage during growth, wherein the inner surface has emissivity coefficients alternating in a circumferential direction.
